(19) United States
(12) Patent Application Publication
(10) Pub. No.: US 2025/0174486 A1
(43) Pub. Date: May 29, 2025

(54) SUBSTRATE TRANSPORT APPARATUS AND SUBSTRATE PROCESSING DEVICE INCLUDING THE SAME

(71) Applicant: SCREEN Holdings Co., Ltd., Kyoto (JP)

(72) Inventors: Hiroyuki KAWAHARA, Kyoto (JP); Takashi OTA, Kyoto (JP); Michinori IWAO, Kyoto (JP); Takuya SATO, Kyoto (JP)

(21) Appl. No.: 18/957,627

(22) Filed: Nov. 22, 2024

(30) Foreign Application Priority Data
Nov. 29, 2023 (JP) 2023-202083

(51) Int. Cl. H01L 21/687; B25J 11/00; H01L 21/68

(52) U.S. Cl. CPC H01L 21/68707; B25J 11/0095; H01L 21/68

(57) ABSTRACT

When a substrate is held by a first hand, a servomotor is operated to move each guide to an outer peripheral surface of the substrate. When a tactile sensor detects that each guide abuts on the outer peripheral surface of the substrate, the servomotor adjusts a biasing force by each guide to the outer peripheral surface of the substrate according to the shape of the substrate. Therefore, the grasping force can be adjusted according to the shape of the substrate such as warpage and a thickness of the substrate. As a result, it is possible to prevent the substrate from being damaged during transportation regardless of the shape of the substrate.

### CROSS-REFERENCE TO RELATED APPLICATIONS

This application claims priority to Japanese Patent Application No. 2023-202083 filed Nov. 29, 2023, the subject matter of which is incorporated herein by reference in entirety.

### BACKGROUND

### Technical Field

The present invention relates to a substrate transport apparatus that transports a substrate such as a semiconductor substrate, a substrate for a flat panel display (FPD) such as a liquid crystal display or an organic electroluminescence (EL) display device, a glass substrate for a photomask, or a substrate for an optical disk, as well as a substrate processing device including such a substrate transport apparatus.

### Related Art

Conventionally, this type of substrate transport apparatus includes a robot hand having a hand main body and a tactile sensor (see JP 2022-91240 A, for example).

The hand main body has a U shape in plan view. The hand main body has bifurcated distal ends. The hand main body is integrated at a proximal end. The hand main body includes tactile sensors at three positions of the two distal ends and the proximal end. The tactile sensors are disposed such that their sensing surfaces are above the hand body. The robot hand supports a lower surface of the substrate in contact with the lower surface at three positions. The robot hand can acquire the support state of the substrate from the tactile sensors. According to the support state, the robot hand may be controlled such as adjusting a transport speed.

### SUMMARY

However, the conventional example having such a configuration has the following problems.

That is, the conventional device is able to normally transport a substrate that satisfies the standard of International Semiconductor Equipment and Materials International: SEMI (Semiconductor Equipment and Materials International), and with less deformation by acquiring the support state of the substrate. On the other hand, when a substrate that does not comply with the SEMI standard, for example, a substrate having a diameter larger than that of the standard or a substrate that is deformed such as warped, is transported, the support state may not be normally acquired. Therefore, depending on the shape of the substrate, appropriate transport according to the support state of the substrate cannot be performed, and the substrate may be damaged at the time of transportation.

In particular, recently, in a power semiconductor or the like, a substrate that is extremely thin may be used. The robot hand may not normally support such a substrate. Further, a thin substrate is likely to be damaged particularly when the substrate is supported. In addition, the substrate may be deformed into a bowl shape (Bowl), an umbrella shape (Umbrella), or a half pipe shape through various heat treatments. Similarly to the above, these substrates may be damaged during transportation.

Conversely, a substrate having a thickness larger than the standard thickness by bonding is also used. Such a substrate can often not be appropriately transported according to the support state of the substrate, and the same problem as described above occurs.

The present invention has been made in view of the above circumstances, and an object of the present invention is to provide a substrate transport apparatus capable of preventing damage to a substrate during transportation from occurring, and a substrate processing device including such a substrate transport apparatus.

In order to achieve the above object, the present invention has the following configuration.

That is, the invention according to claim 1 is a substrate transport apparatus that transports a substrate, the apparatus comprising: a hand configured to hold the substrate in a horizontal posture; a horizontal drive mechanism configured to drive the hand to advance and retreat in a horizontal plane in order to transfer the substrate; at least two guides disposed on the hand, and configured to hold the substrate away from the hand by grasping an outer peripheral surface of the substrate; an advance and retreat drive mechanism configured to drive at least one of the at least two guides as a movable guide to advance and retreat with respect to the substrate; and a control unit configured to control the advance and retreat drive mechanism to adjust a biasing force by the movable guide to the outer peripheral surface of the substrate.

According to the invention of claim 1, when the substrate is held by the hand, the control unit operates the advance and retreat drive mechanism to move the movable guide to the outer peripheral surface of the substrate. The control unit adjusts the biasing force of the movable guide to the outer peripheral surface of the substrate by controlling the advance and retreat drive mechanism. Therefore, the grasping force can be adjusted according to the shape of the substrate such as warpage and a thickness of the substrate, a transport speed of the substrate, and a transport mode such as turning and inversion. As a result, it is possible to prevent the substrate from being damaged when the substrate is transported.

Further, in the present invention, it is preferable that the control unit adjusts the biasing force of the movable guide to the outer peripheral surface of the substrate according to a shape of the substrate (claim 2).

The grasping force can be adjusted according to the shape of the substrate such as warpage or a thickness of the substrate. Therefore, it is possible to prevent the substrate from being damaged when the substrate is transported regardless of the shape of the substrate.

Further, in the present invention, it is preferable that the control unit adjusts the biasing force of the movable guide to the outer peripheral surface of the substrate such that the biasing force decreases as a thickness of the substrate decreases (claim 3).

The grasping force can be adjusted according to the thickness of the substrate. Therefore, it is possible to prevent the substrate from being damaged when the substrate is transported regardless of the thickness of the substrate.

Further, in the present invention, it is preferable that the control unit adjusts the biasing force of the movable guide to the outer peripheral surface of the substrate such that the biasing force decreases as warpage of the substrate increases (claim 4).

The grasping force can be adjusted according to the warpage of the substrate. Therefore, it is possible to prevent the substrate from being damaged when the substrate is transported regardless of the warpage of the substrate.

Further, in the present invention, it is preferable that an outer peripheral surface detection unit configured to detect that the movable guide abuts on the outer peripheral surface of the substrate is further provided, and the control unit adjusts the biasing force after the outer peripheral surface detection unit detects that the movable guide abuts on the outer peripheral surface of the substrate (claim 5).

The control unit adjusts the biasing force after the outer peripheral surface detection unit detects that the movable guide abuts on the outer peripheral surface of the substrate. Therefore, the movable guide can be moved at a high speed until the movable guide abuts on the outer peripheral surface of the substrate. As a result, the time until the hand holds the substrate can be shortened.

Further, in the present invention, it is preferable that all of the guides are movable guides, and when the substrate is held by the hand, the control unit moves all of the movable guides to the outer peripheral surface of the substrate by operating respective advance and retreat drive mechanisms, and adjusts biasing forces by the all of the movable guides by the respective advance and retreat drive mechanisms (claim 6).

All of the guides are movable guides, and the biasing force is adjusted for all of the movable guides. Therefore, when the substrate is grasped, the distance by which the lower surface of the substrate slides in the horizontal direction at the place where the substrate is placed can be shortened. As a result, even when the position where the substrate is placed is shifted, movement of the center position of the substrate when the substrate is grasped is minimized. Therefore, it is possible to suppress particles generated as the substrate is grasped.

Further, in the present invention, it is preferable that the outer peripheral surface detection unit is a tactile sensor including a detection surface capable of detecting a force applied to each of three orthogonal axes (claim 7).

The reaction force received by the movable guide from the outer peripheral surface of the substrate can be detected regardless of the posture when the outer peripheral surface of the substrate abuts on the movable guide. Therefore, it is possible to accurately detect that the movable guide abuts on the outer peripheral surface of the substrate.

Further, in the present invention, it is preferable that the advance and retreat drive mechanism includes a motor, a drive circuit, and an encoder, the motor driving the guide to advance and retract, the drive circuit applying a drive current for driving the motor, the encoder detecting a rotational position of the motor, the outer peripheral surface detection unit includes at least one of a drive current detection unit and a position information detection unit, the drive current detection unit detecting the abutment based on drive current information of the drive circuit, the position information detection unit detecting the abutment based on position information output from the encoder, and the control unit determines the abutment based on at least one of the drive current information and the position information (claim 8).

The control unit determines that the movable guide abuts on the outer peripheral surface of the substrate based on at least one of the drive current information from the drive current detection unit and the position information from the encoder. Therefore, it is not necessary to provide a sensor that detects abutment between the guide and the outer peripheral surface of the substrate. As a result, it is possible to simplify the structure and to suppress the cost.

Further, in the present invention, it is preferable that the outer peripheral surface detection unit is provided for the movable guide at an attachment portion to the hand (claim 9).

Since the outer peripheral surface detection unit is provided at the attachment portion where the movable guide is attached to the hand, the reaction force received from the substrate can be detected with high sensitivity. Therefore, it is possible to detect that the movable guide abuts on the outer peripheral surface of the substrate with high accuracy.

Further, in the present invention, it is preferable that the guide is attached to a lower surface of the hand (claim 10).

Even if a clearance as the distance between an upper surface of the placement unit as a transfer destination of the substrate and a lower surface of the substrate is small, the substrate can be transferred to and from the placement unit from above by the guide provided on the lower surface of the hand.

Further, in the present invention, it is preferable that the guide has a columnar shape (claim 11).

When the substrate has a circular shape, the guide having a columnar shape and the outer peripheral surface of the substrate are in point contact with each other. Therefore, an area of contact can be minimized, and mutual contamination via the guide can be suppressed.

Further, in the present invention, it is preferable that the guide includes an inclined surface and a grasping portion, the inclined surface being lowered toward a center side of the substrate, the grasping portion being erected along the outer peripheral surface of the substrate, when receiving the substrate, the hand grasps the substrate by pressing the substrate against the grasping portion by the movable guide applying a biasing force to the outer peripheral surface of the substrate after the substrate is once placed on the inclined surface, and the guide includes a placement detection unit configured to detect that the substrate is placed on the inclined surface (claim 12).

The placement detection unit can detect that the substrate is placed on the inclined surface of the guide. Therefore, the presence or absence of the substrate can be accurately detected.

Further, in the present invention, it is preferable that the hand further includes a nozzle configured to supply a treatment liquid to an upper surface of the substrate grasped by the guide (claim 13).

In a substrate on which a pattern having a three-dimensional structure is formed, the pattern may collapse due to an influence of a gas-liquid interface when the substrate is dried. Therefore, the substrate is transported in a state in which the substrate is wet with pure water so that the substrate is not dried. Since the hand includes the nozzle, the substrate can be transported while the substrate is maintained in a wet state. Therefore, even if the substrate is transported in the wet state, a decrease in throughput can be suppressed.

Further, in the present invention, it is preferable that the hand includes two extending portions and a beam portion, the extending portions extending from a proximal end to a distal end, the beam portion being suspended between the two extending portions so as to pass through a center portion of the substrate grasped by the hand, and the nozzle is provided for the beam portion and supplies the treatment liquid to the substrate grasped by the hand (claim 14).

Since the nozzle is provided in the beam portion suspended between the two extending portions, the treatment liquid can be supplied to the central portion of the substrate. Therefore, the treatment liquid can be supplied over the entire surface of the substrate.

Further, in the present invention, it is preferable that the hand includes two types of pickup hands including an upper pickup hand having the guide on a lower surface thereof and a lower pickup hand having the guide on an upper surface thereof, and according to a clearance as a distance between an upper surface of a t as a transfer destination and a lower surface of the substrate, the substrate is transferred to and from the placement unit by using the lower pickup hand for the placement unit having a large clearance, and using the upper pickup hand for the placement unit having a small clearance (claim 15).

The substrate can be transferred to and from the placement unit using the lower pickup hand for the placement unit having a large clearance and using the upper pickup hand for the placement unit having a small clearance. Therefore, the substrate can be reliably transported by selecting an appropriate hand according to the clearance of the placement unit.

Further, the present invention preferably includes the substrate transport apparatus described above; and a processor configured to perform predetermined processing on the substrate (claim 16).

When the substrate is transported to and from the processor, the grasping force can be adjusted according to the shape of the substrate such as warpage and a thickness of the substrate. As a result, in the substrate processing device, it is possible to prevent the substrate from being damaged during transportation regardless of the shape of the substrate.

Note that the present specification also discloses the invention related to a substrate transport apparatus and a substrate processing device including such a substrate transport apparatus as described below.

In recent years, in the semiconductor field, a pattern of a three-dimensional structure has become increasingly fine. In a substrate on which a pattern having a three-dimensional structure is formed, the pattern may collapse due to an influence of a gas-liquid interface when the substrate is dried. Therefore, after a treatment by a batch type module in which a plurality of substrates are collectively treated, the substrates are brought into a wet state with pure water so that the substrates are not dried until a treatment in a single wafer type module in which each substrate is treated is performed.

However, in the conventional substrate transport apparatus having a robot hand including a hand main body and a tactile sensor, even if pure water is poured on the upper surface of the substrate, the pure water may spill from the upper surface of the substrate placed on the hand main body during transportation. Therefore, in order to transport the substrate in a wet state, it is necessary to transport the substrate at very low speed, and there is a problem that the throughput needs to be extremely lowered.

An object of the present invention is to provide a substrate transport apparatus capable of suppressing a decrease in throughput even when a substrate is transported in a wet state, and a substrate processing device including such a substrate transport apparatus.

(1) A substrate transport apparatus that transports a substrate, the apparatus including:
a hand configured to hold the substrate in a horizontal posture;
a horizontal drive mechanism configured to drive the hand to advance and retreat in a horizontal plane in order to transfer the substrate;
at least three guides disposed on a lower surface of the hand, and configured to hold the substrate away from the lower surface of the hand by grasping an outer peripheral surface of the substrate; and
a nozzle provided for the hand and configured to supply a treatment liquid to an upper surface of the substrate held by the hand.

According to the invention described in (1), since the hand includes the nozzle, the substrate can be transported while the substrate is maintained in a wet state. Therefore, it is possible to suppress a decrease in throughput even when the substrate is transported in a wet state.

(2) The substrate transport apparatus according to (1), wherein
the hand includes two extending portions and a beam portion, the extending portions extending from a proximal end to a distal end, the beam portion being suspended between the two extending portions so as to pass through a center portion of the substrate grasped by the hand, and
the nozzle is provided for the beam portion and supplies the treatment liquid to the substrate grasped by the hand.

According to the invention described in (2), since the nozzle is provided in the beam portion suspended between the two extending portions, the treatment liquid can be supplied to the central portion of the substrate. Therefore, the treatment liquid can be supplied over the entire surface of the substrate.

(3) A substrate processing device including:
a batch-type processing unit configured to collectively process a plurality of substrates in a vertical posture;
a single-wafer-type processing unit configured to process a single substrate in a horizontal posture;
a posture converting unit configured to hold the plurality of substrates that have been processed by the batch-type processing unit, and convert the vertical posture of the substrates to the horizontal posture;
a first transport unit configured to transport the plurality of substrates, that have been processed by the batch-type processing unit to the posture converting unit; and
a second transport unit configured to transport the substrates whose posture is converted to the horizontal posture by the posture converting unit to the single-wafer-type processing unit, wherein
the second transport device is the substrate transport apparatus according to (1) or (2).

According to the invention described in (3), the first transport unit transports the substrates from the batch-type processing unit to the posture converting unit after the processing by the batch-type processing unit that collectively processes the plurality of substrates. The second transport unit transports the substrates brought into the horizontal posture by the posture converting unit to the single-wafer-type processing unit that processes the substrates one by one. Since the second transport unit supplies the treatment liquid from the nozzle to the substrate, the substrate can be transported while the substrate is maintained in a wet state. Therefore, even if the substrate is transported in the wet state, a decrease in throughput can be suppressed.

According to the substrate transport apparatus of the present invention, when the substrate is held by the hand, the control unit operates the advance and retreat drive mechanism to move the movable guide to the outer peripheral surface of the substrate. The control unit adjusts the biasing force of the movable guide to the outer peripheral surface of the substrate by controlling the advance and retreat drive mechanism. Therefore, the grasping force can be adjusted according to the shape of the substrate such as warpage and a thickness of the substrate, a transport speed of the substrate, and a transport mode such as turning and inversion. As a result, it is possible to prevent the substrate from being damaged when the substrate is transported.

### BRIEF DESCRIPTION OF DRAWINGS

FIG. 1 is a plan view illustrating a schematic configuration of a substrate processing device according to a first embodiment;

FIG. 2 is a view of the substrate processing device of FIG. 1 as viewed from a rear side X;

FIGS. 3A to 3E are side views illustrating a configuration and an operation of a carry-in and carry-out block;

FIG. 4 is a side view illustrating a first example of a placement unit included in a processing unit;

FIG. 5 is a side view illustrating a second example of the placement unit included in the processing unit;

FIG. 6 is a plan view of a lower pickup hand according to the first embodiment;

FIG. 7 is a side view of a hand according to the first embodiment;

FIG. 8 is a longitudinal sectional view illustrating a configuration of a movable guide on a side of a distal end;

FIG. 9 is a longitudinal sectional view illustrating a configuration of the movable guide (pusher) on a side of a proximal end;

FIG. 10 is a side view of an upper pickup hand according to the embodiment;

FIG. 11 is a block diagram illustrating a control system;

FIG. 12 is a flowchart for explaining an operation related to transportation;

FIG. 13 is a schematic view for explaining an operation as viewed from a side;

FIG. 14 is a schematic view for explaining an operation as viewed from a plane;

FIG. 15 is a schematic view for explaining an operation as viewed from a side;

FIG. 16 is a schematic view for explaining an operation as viewed from a plane;

FIG. 17 is a schematic view for explaining an operation as viewed from a side;

FIG. 18 is a schematic view for explaining an operation as viewed from a plane;

FIG. 19 is a schematic view for explaining an operation as viewed from a side;

FIG. 20 is a schematic view for explaining an operation as viewed from a plane;

FIG. 21 is a schematic view for explaining an operation as viewed from a side;

FIG. 22 is a schematic view for explaining an operation as viewed from a side;

FIG. 23 is a side view of a hand of a substrate processing device according to a second embodiment;

FIG. 24 is a block diagram illustrating a control system of a substrate processing device according to the second embodiment;

FIG. 25 is a plan view of a hand of a substrate processing device according to a third embodiment;

FIG. 26 is a view taken along a line indicated by arrows 100-100 viewed in a direction of the arrows in FIG. 25;

FIG. 27 is a flowchart for explaining an operation related to transportation;

FIG. 28 is a plan view illustrating a schematic configuration of a substrate processing device according to a fourth embodiment;

FIG. 29 is a side view of an underwater posture converting unit; and

FIG. 30 is a plan view of a hand of a substrate processing device according to the fourth embodiment as viewed from below.

### DETAILED DESCRIPTION

The present invention will be described below with reference to various embodiments.

### First Embodiment

Hereinafter, a first embodiment of the present invention will be described with reference to the drawings.

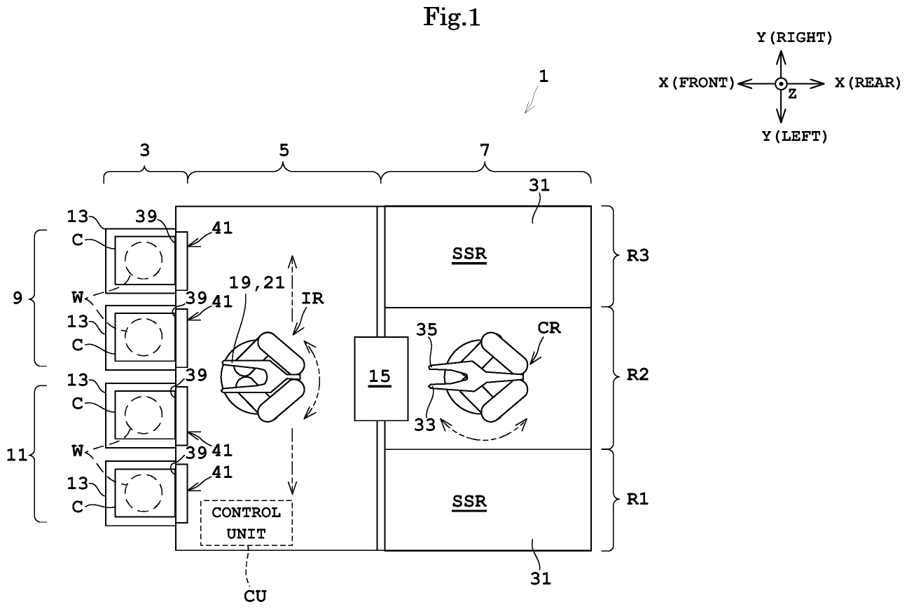

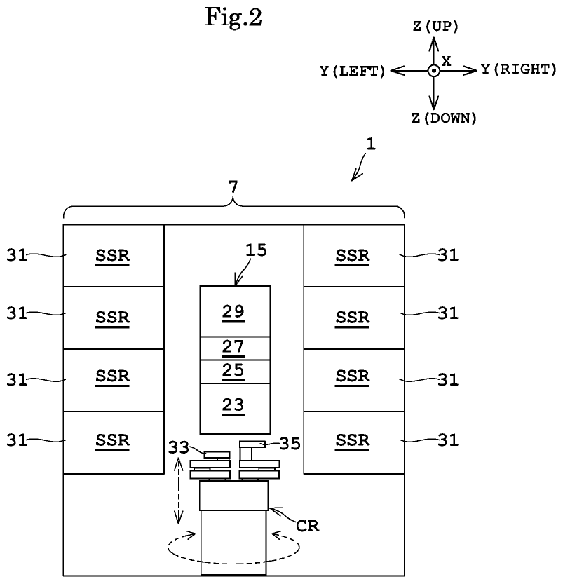

FIG. 1 is a plan view illustrating an overall configuration of a substrate processing device according to the first embodiment. FIG. 2 is a view of the substrate processing device of FIG. 1 as viewed from a rear side X.

### <1. Overall Configuration>

The substrate processing device 1 includes a carry-in and carry-out block 3, an indexer block 5, and a processing block 7.

The substrate processing device 1 processes a substrate W. The substrate processing device 1 performs, for example, cleaning treatment on the substrate W. In the processing block 7, the substrate processing device 1 performs single wafer processing on the substrate W. In the single wafer processing, a single substrate W is processed in a horizontal posture one by one. The substrate W has, for example, a circular shape in plan view.

In the present specification, for convenience, a direction in which the carry-in and carry-out block 3, the indexer block 5, and the processing block 7 are arranged is referred to as a “front-rear direction X”. The front-rear direction X is horizontal. Of the front-rear direction X, a direction from the processing block 7 toward the carry-in and carry-out block 3 is referred to as “front”. A direction opposite to the front is referred to as “rear”. A horizontal direction orthogonal to the front-rear direction X is referred to as a “width direction Y”. One direction in the “width direction Y” is appropriately referred to as a “right side”. A direction opposite to the right side is referred to as a “left side”. A direction perpendicular to the horizontal direction is referred to as a “vertical direction Z”. In each drawing, front, back, right, left, up, and down are appropriately shown for reference.

### <2. Carry-In and Carry-Out Block>

The carry-in and carry-out block 3 includes a load unit 9 and an unload unit 11. The load unit 9 and the unload unit 11 are disposed in the width direction Y. A plurality of (for example, 25 sheets) substrates W are stacked and stored at constant intervals in a horizontal posture in one carrier C. The carrier C storing unprocessed substrates W is placed on the load unit 9. The load unit 9 includes, for example, two placement tables 13 on which the carrier C is placed. In the carrier C, a plurality of grooves (not illustrated) for accommodating the substrates W one by one with surfaces of the substrates W separated from each other are provided. The carrier C accommodates the substrates W, for example, in a posture in which the surfaces of the substrates W face upward. Examples of the carrier C include a front opening unify pod (FOUP). The FOUP is a closed-type container. The carrier C may be an open-type container or of any type.

The unload unit 11 is disposed on the opposite side of the load unit 9 across the central portion in the width direction Y of the substrate processing device 1. The unload unit 11 is disposed on the left side Y of the load unit 9. The unload unit 11 places the processed substrates W in the carrier C and unloads the processed substrates W with the carrier C in whole. Similarly to the load unit 9, the unload unit 11 functioning in this manner includes, for example, two placement tables 13 for placing the carrier C. The load unit 9 and the unload unit 11 are also called load ports.

### <3. Indexer Block>

The indexer block 5 is disposed adjacent to the carry-in and carry-out block 3 on the rear side X in the substrate processing device 1. The indexer block 5 includes an indexer robot IR and a transfer unit 15.

The indexer robot IR is configured to be rotatable around the vertical direction Z. The indexer robot IR is configured to be movable in the width direction Y. The indexer robot IR includes a first hand 19 and a second hand 21. FIG. 1 illustrates only one hand for the sake of illustration. The first hand 19 and the second hand 21 hold the substrate W in a horizontal posture. The first hand 19 and the second hand 21 grasp the outer peripheral surface of the substrate W and hold the substrate W to be separated from the upper surfaces of the first hand 19 and the second hand 21.

Each of the first hand 19 and the second hand 21 holds one substrate W. The first hand 19 and the second hand 21 are independently movable forward and backward in the front-rear direction X. The indexer robot IR moves in the width direction Y and rotates around the vertical direction Z, and advances and retracts the first hand 19 and the second hand 21 to transfer the substrate W to and from the respective carriers C. Similarly, the indexer robot IR delivers the substrate W to and from the transfer unit 15.

The transfer unit 15 is disposed at a boundary with the processing block 7 in the indexer block 5. The transfer unit 15 is disposed, for example, at a central part in the width direction Y. As illustrated in FIG. 2, the transfer unit 15 is provided elongated in the vertical direction Z.

The transfer unit 15 includes a first reversing unit 23, a pass portion 25, a pass portion 27, and a second reversing unit 29 from a lower side to an upper side in the vertical direction Z.

The first reversing unit 23 vertically flips the substrate W received from the indexer block 5. The first reversing unit 23 reverses the horizontal posture of the substrate W. Specifically, the first reversing unit 23 converts the posture of the substrate W from the posture with a front surface facing upward to the posture with the front surface facing downward. In other words, the posture of the substrate W is changed so that its back surface faces upward.

The second reversing unit 29 performs a reverse operation. That is, the second reversing unit 29 vertically flips the substrate W received from the processing block 7. The second reversing unit 29 converts the posture of the substrate W from the posture with the front surface facing downward to the posture with the front surface facing upward. In other words, the posture of the substrate W is changed so that the back surface faces downward.

The reversing directions by the first reversing unit 23 and the second reversing unit 29 may be opposite to each other. That is, the first reversing unit 23 changes the posture of the substrate W so that the surface faces upward. The second reversing unit 29 changes the posture of the substrate W so that the back surface faces upward.

The pass portions 25 and 27 are used to transfer the substrates W between the indexer block 5 and the processing block 7. The pass portion 25 is used, for example, to transport the substrate W from the processing block 7 to the indexer block 5. The pass portion 27 is used, for example, to transport the substrate W from the indexer block 5 to the processing block 7. Note that the transport directions of the substrates W in the pass portions 25 and 27 may be opposite to each other.

### <4. Processing Block>

The processing block 7 performs, for example, various types of treatments on the substrate W. Examples of the treatment include a cleaning treatment. The cleaning treatment is, for example, a treatment liquid cleaning treatment performed by supplying only a cleaning liquid, or a brush cleaning treatment using a brush in addition to the treatment liquid.

As illustrated in FIG. 1, for example, the processing block 7 is divided into a first row R1, a second row R2, and a third row R3 in the width direction Y. Specifically, the first row R1 is arranged on the left side Y. The second row R2 is disposed at the center portion in the width direction Y. In other words, the second row R2 is arranged on the right side Y of the first row R1. The third row R3 is arranged on the right side Y of the second row R2.

### <4-1. First Row>

The first row R1 of the processing block 7 includes a plurality of processing units 31. The first row R1 includes, for example, four processing units 31. In the first row R1, the four processing units 31 are disposed in a stacked manner in the vertical direction Z. Each of the processing units 31 is a cleaning unit, for example. The cleaning units performs a cleaning treatment to the substrate W. Examples of the cleaning unit include a front surface cleaning unit for performing a cleaning treatment to the front surface of the substrate W and a back surface cleaning unit for performing a cleaning treatment to the back surface of the substrate W. In the present embodiment, a back surface cleaning unit SSR will be described as an example of the processing units 31.

### <4-2. Second Row>

The second row R2 of the processing block 7 includes a center robot CR. The center robot CR is configured to be rotatable around the vertical direction Z. The center robot CR is configured to be movable up and down in the vertical direction Z. The center robot CR includes, for example, a first hand 33 and a second hand 35. Each of the first hand 33 and the second hand 35 holds one substrate W. The first hand 33 and the second hand 35 are independently movable forward and backward in the front-rear direction X and the width direction Y.

The first hand 33 and the second hand 35 hold the substrate W in the horizontal posture. The first hand 33 and the second hand 35 grasp the outer peripheral surface of the substrate W and hold the substrate W to be separated from the upper surfaces of the first hand 33 and the second hand 35.

### <4-3. Third Row>

The third row R3 of the processing block 7 has the same configuration as the first row R1. That is, the third row R3 includes the plurality of processing units 31. The third row R3 includes, for example, four processing units 31. In the third row R3, the four processing units 31 are disposed in a stacked manner in the vertical direction Z. The processing units 31 in the first row R1 and the processing units 31 in the third row R3 are arranged to face each other in the width direction Y. As a result, the center robot CR can access the processing units 31 of the first row R1 and the third row R3 facing each other at the same height in the vertical direction Z.

The processing block 7 is configured as described above. Here, an operation example of the center robot CR will be briefly described. The center robot CR receives the substrate W from the first reversing unit 23, for example. The center robot CR transports the substrate W to the back surface cleaning unit SSR in one of the first row R1 and the third row R3, and causes the back surface cleaning unit SSR to perform a cleaning treatment to the back surface of the substrate W to be cleaned. The center robot CR receives the substrate W subjected to the cleaning treatment in the back surface cleaning unit SSR in one of the first row R1 and the third row R. The center robot CR transports the substrate W to the second reversing unit 29. The indexer robot IR receives the substrate W from the second reversing unit 29 and stores the substrate W in the carrier C.

### <5. Placement Table>

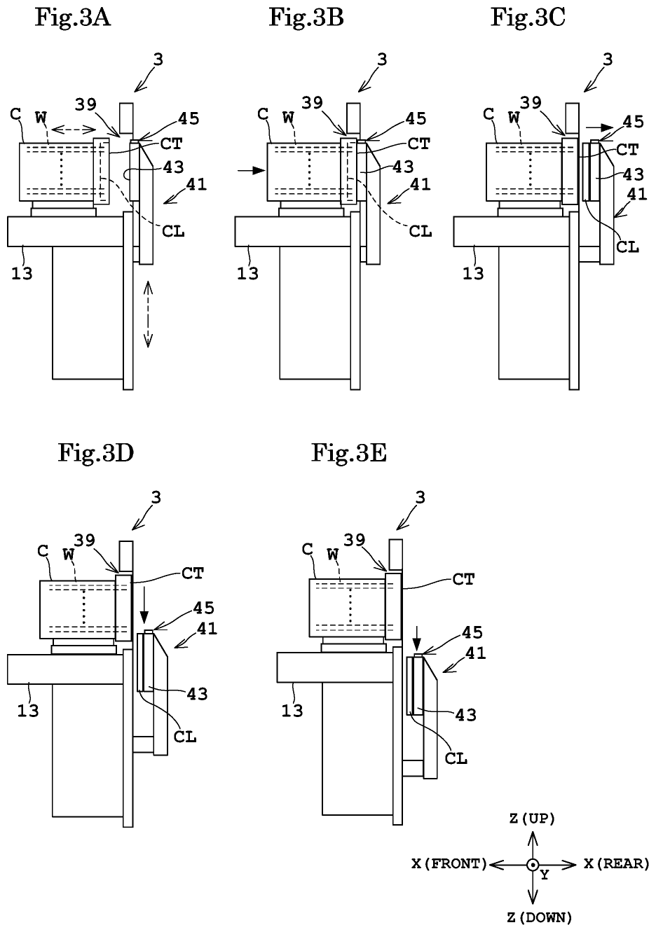

Here, the above-described carry-in and carry-out block 3 will be described in detail with reference to FIGS. 1, and 3A to 3E. FIGS. 3A to 3E are side views illustrating a configuration and an operation of the carry-in and carry-out block.

The carry-in and carry-out block 3 includes a placement table 13, an opening 39, and a lid opening and closing mechanism 41. The carrier C is placed on the placement table 13. The placement table 13 includes a mechanism (not illustrated) that moves the carrier C in the front-rear direction X. The placement table 13 can advance and retract the carrier C with respect to the opening 39. The carrier C has a carry-in and carry-out port CT. The carry-in and carry-out port CT is provided on one side surface of the carrier C. The plurality of substrates W stacked and accommodated in the carrier C are carried in and out through the carry-in and carry-out port CT. The carrier C includes a lid CL. The lid CL is configured to be detachable from the carry-in and carry-out port CT of the carrier C. The lid CL seals an interior of the carrier C. When the lid CL is attached to the carrier C, the atmosphere outside of the carrier C is blocked.

The lid opening and closing mechanism 41 includes a detachable unit 43 on the front side X. The detachable unit 43 detaches the lid CL from the carrier C and attaches the lid CL to the carrier C. The detachable unit 43 is movable in the vertical direction Z and the front-rear direction X in a state in which the detachable unit 43 holds the lid CL. The lid opening and closing mechanism 41 is movable in the front-rear direction X at the opening 39 in a state in which the lid opening and closing mechanism 41 holds the lid CL. The lid opening and closing mechanism 41 can be raised and lowered in the vertical direction Z in the state in which the lid opening and closing mechanism 41 holds the lid CL. The lid opening and closing mechanism 41 can move downward in the vertical direction Z from the opening 39 in the state in which the lid opening and closing mechanism 41 holds the lid CL. The lid opening and closing mechanism 41 can fully open the opening 39 by moving downward in the state in which the lid opening and closing mechanism 41 holds the lid CL.

First, as illustrated in FIG. 3A, the carrier C is placed on the placement table 13. The plurality of substrates W are stacked and accommodated in the carrier C, and the carrier C is closed by the lid CL. At this time, the lid opening and closing mechanism 41 positions the detachable unit 43 in the opening 39. Accordingly, an interior of the indexer block 5 is separated from the external atmosphere.

As illustrated in FIG. 3B, the placement table 13 moves the carrier C to the rear side X. In the carrier C, the carry-in and carry-out port CT and the lid CL are located at the opening 39. At this time, the detachable unit 43 unlocks the lid CL and holds the lid CL. The holding is performed, for example, by the detachable unit 43 sucking the lid CL.

As shown in FIG. 3C, the lid opening and closing mechanism 41 moves to the rear side X. Thus, the lid CL is moved from the opening 39 to the rear side X. The lid CL is moved into the interior of the indexer block 5.

As shown in FIG. 3D, the lid opening and closing mechanism 41 moves downward in the vertical direction Z. The lid opening and closing mechanism 41 lowers the detachable unit 43 to a lower part of the carry-in and carry-out port CT. The lid opening and closing mechanism 41 is lowered until an upper part of the detachable unit 43 is positioned at a lower part of the opening 39.

As shown in FIG. 3E, the lid opening and closing mechanism 41 moves downward in the vertical direction Z, and moves to a lowermost part at which the lid opening and closing mechanism 41 can reach. The lid opening and closing mechanism 41 is lowered to a position where the detachable unit 43 does not overlap the opening 39 in the front-rear direction X. As a result, the opening 39 is fully opened. The plurality of substrates W in the carrier C can be seen from the indexer block 5 through the opening 39.

The lid opening and closing mechanism 41 described above includes a substrate sensor 45 in the detachable unit 43, for example. The substrate sensor 45 is used to detect positions of the substrates W stacked and stored in the carrier C and collect shape information based on an outer edge of the substrate W. The shape information includes information on a thickness based on the outer edge of the substrate W.

### <6. Placement Unit>

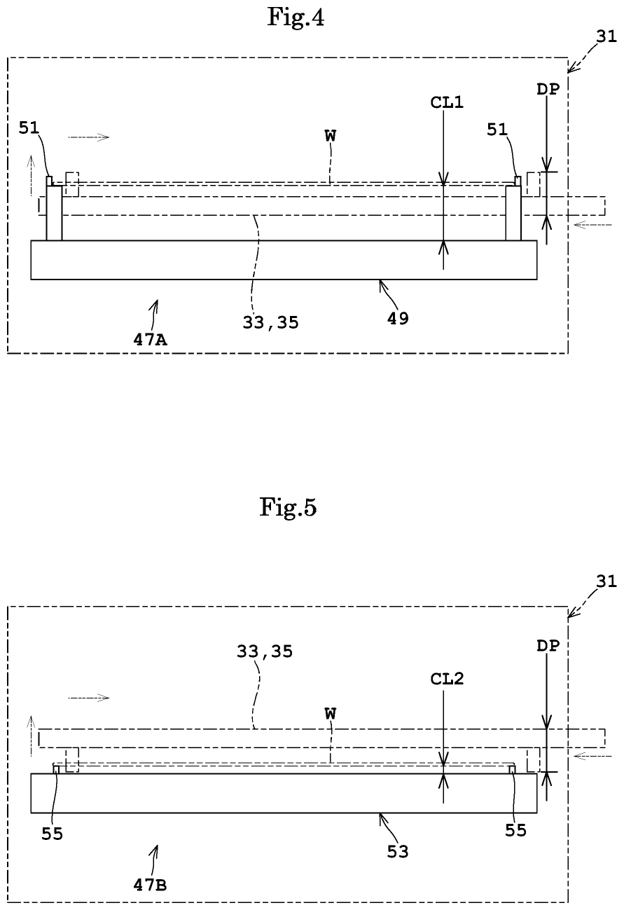

Here, a part of the processing unit 31 described above will be described with reference to FIGS. 4 and 5. FIG. 4 is a side view illustrating a first example of the placement unit included in the processing unit. FIG. 5 is a side view illustrating a second example of the placement unit included in the processing unit.

The processing unit 31 described above is the back surface cleaning unit SSR. The back surface cleaning unit SSR includes, for example, one of two types of placement units 47 (placement units 47A and 47B) as described below. The placement unit 47 is a place where the substrate W is placed in the back surface cleaning unit SSR. The placement unit 47 supports a lower surface of the substrate W. In addition to the two types of placement units 47 (placement units 47A and 47B), there is also a placement unit that holds the substrate W by suction.

As illustrated in FIG. 4, the placement unit 47A includes a rotating table 49 and support pins 51. The rotating table 49 has a circular shape in plan view. The rotating table 49 has a diameter slightly larger than that of the substrate W. A number of the support pins 51 is more than one. The support pins 51 are erected on an upper surface of the rotating table 49. The support pins 51 are disposed on an upper surface slightly inside an outer peripheral surface of the rotating table 49. Some of the support pins 51 rotate eccentrically about an axis in the vertical direction Z. The substrate W is pressed from the outer peripheral surface in the horizontal direction by the support pins 51 rotating in this manner, and the position is fixed by the plurality of support pins 51. The support pins 51 are in contact with the outer peripheral surface and the lower surface of the substrate W to support the lower surface of the substrate W away from the upper surface of the rotating table 49.

Here, an interval between the upper surface of the rotating table 49 and the lower surface of the substrate W supported by the support pins 51 is referred to as a clearance CL1. The placement unit 47A of the first example has a relatively large clearance CL1. The clearance CL1 is larger than a thicknesses DP of the first hand 33 and the second hand 35. The thickness DP corresponds to a maximum height of the hands in the vertical direction Z when a portion of the first hand 33 and the second hand 35 that reaches a position for transfer of the substrate W is viewed from the side.

In the cleaning unit SSR including the placement unit 47A, it is preferable to access the cleaning unit SSR with a lower pickup hand described later. The placement unit 47A can be accessed by an upper pickup hand described later.

As illustrated in FIG. 5, the placement unit 47B includes a rotating table 53 and support projections 55. The rotating table 53 has a circular shape in plan view. The rotating table 53 includes an injection port (not illustrated) for supplying a gas to the lower surface of the substrate W. The support projections 55 are provided on an upper surface of the rotating table 53. A number of the support projections 55 is more than one. The support projections 55 are provided slightly inside an outer peripheral surface of the rotating table 53. The support projections 55 are in contact with the lower surface of the substrate W to support the lower surface of the substrate W away from the upper surface of the rotating table 53. The substrate W is supported so as to be sucked by the support projections 55 and the rotating table 53 by a negative pressure generated by supplying a gas. As a result, the position of the substrate W is fixed. A clearance CL2 of the placement unit 47B is relatively small. The clearance CL2 is smaller than the clearance CL1. The clearance CL2 is smaller than the thicknesses DP of the first hand 33 and the second hand 35.

In the cleaning unit SSR including the placement unit 47B, it is preferable to access the cleaning unit SSR with an upper pickup hand described later.

### <7. Details of Hand>

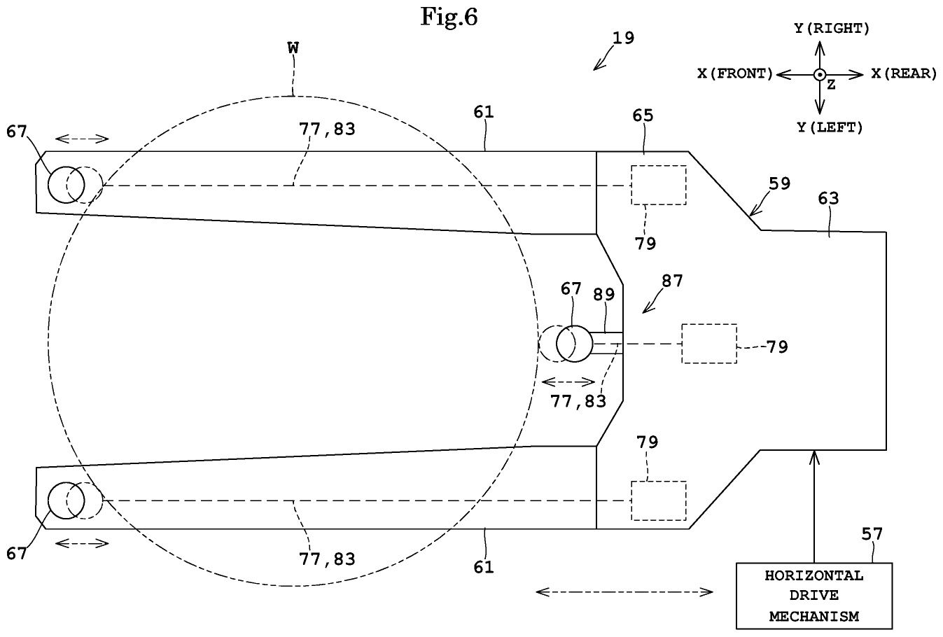

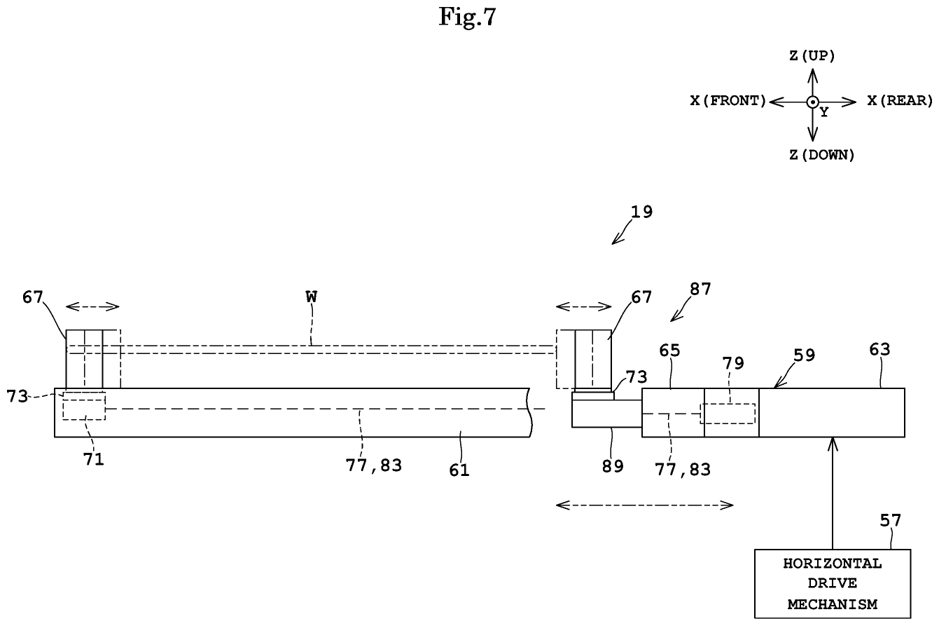

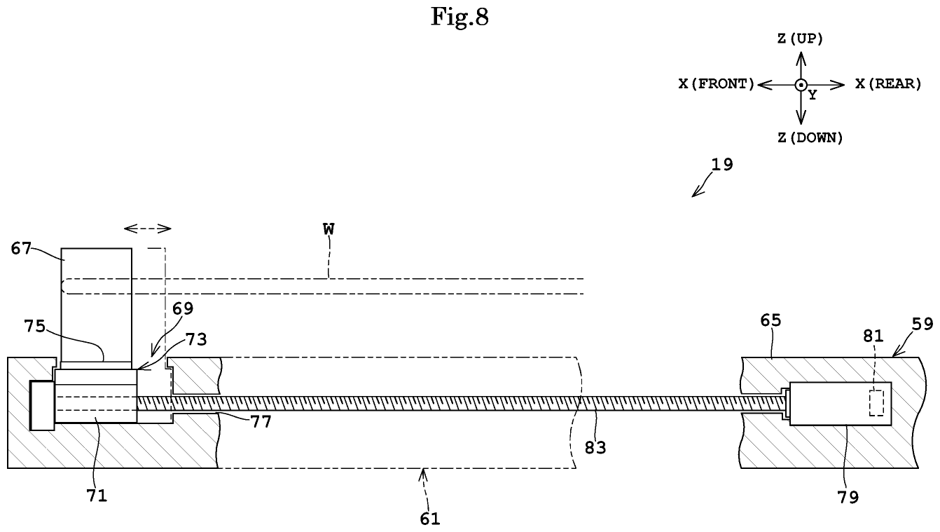

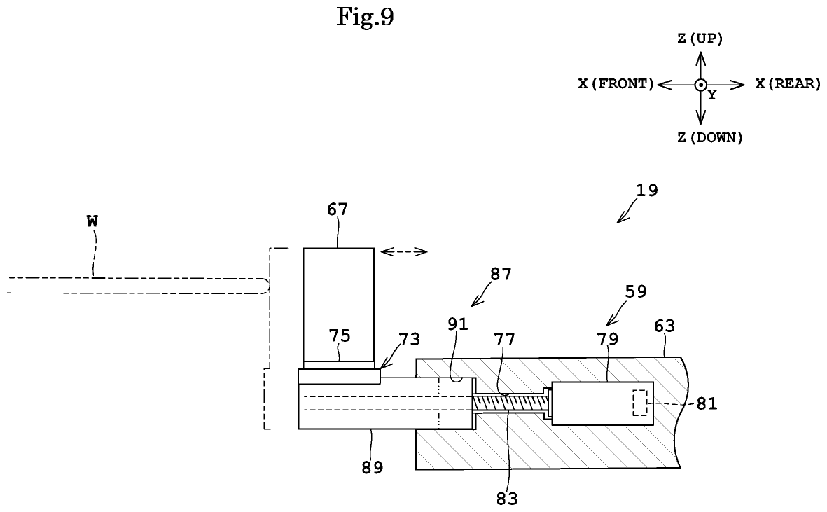

Here, the first hand 19 in the indexer robot IR will be described as an example with reference to FIGS. 6 to 9. FIG. 6 is a plan view of the lower pickup hand according to the first embodiment. FIG. 7 is a side view of the hand according to the first embodiment. FIG. 8 is a longitudinal sectional view illustrating a configuration of a movable guide on a side of a distal end. FIG. 9 is a longitudinal sectional view illustrating a configuration of the movable guide (pusher) on a side of a proximal end. Note that the configuration of the first hand 19 is the same as that of the second hand 21, and of the first hand 33 and the second hand 35 in the center robot CR.

The indexer robot IR includes a horizontal drive mechanism 57. The horizontal moving mechanism 57 drives the first hand 19 in the front-rear direction X. The horizontal moving mechanism 57 drives the first hand 19 to move forward and backward in the horizontal direction. The horizontal moving mechanism 57 drives the first hand 19 forward and backward with respect to a transfer destination. Specifically, the transfer destination in the indexer robot IR is driven forward and backward with respect to the carrier C and the transfer unit 15. The horizontal moving mechanism 57 in the center robot CR drives the first hand 33 and the second hand 35 forward and backward in the front-rear direction X as well as in the width direction Y.

The first hand 19 includes one palm portion 59 and two finger portions 61. The palm portion 59 is on the side of the proximal end of the first hand 19. The finger portions 61 are on the side of the distal end of the first hand 19. The transfer destination enters from the side of the distal end of the first hand 19 and exits from the side of the proximal end of the first hand 19. The palm portion 59 includes an attachment proximal end 63 and finger portion attachment portions 65. The attachment proximal end 63 is attached to the horizontal drive mechanism 57. The finger portions 61 are attached to the finger portion attachment portions 65. The finger portion attachment portions 65 are provided at two positions spaced apart in the width direction Y. Portions of the finger portion attachment portions 65 to which the two finger portions 61 are respectively attached are located outside the outer peripheral surface of the substrate W in plan view when the first hand 19 advances to the position for transfer of the substrate W. In other words, a length of the finger portions 61 in the front-rear direction X is longer than the diameter of the substrate W.

The first hand 19 includes the two finger portions 61. The two finger portions 61 extend in the front-rear direction X. The two finger portions 61 are separated from each other in the width direction Y. A distance by which the two finger portions 61 are separated from each other does not exceed the diameter of the substrate W. In other words, the width direction Y of the two finger portions 61 falls within the diameter of the substrate W. The finger portion 61 is attached to the finger portion attachment portion 65 on the side of the proximal end. The side of the distal end on an opposite of the side of the proximal end of the finger portion 61 is in an open state. The first hand 19 has a U shape in plan view with the palm portion 59 and the two finger portions 61.

The first hand 19 includes three guides 67. The three guides 67 are attached to the upper surface of the first hand 19. The finger portion 61 includes one of the guides 67 on the side of the distal end. A structure in which the guides 67 are provided on the upper surface of the finger portion 61 like the first hand 19 is referred to as “lower pickup hand”. The first hand 19 having a structure of the lower pickup hand holds the substrate W by scooping up the substrate W from below to above.

As illustrated in FIG. 8, the guide 67 of the finger portion 61 is attached in a guide hole 69. The guide hole 69 is elongated in the front-rear direction X. A moving piece 71 is disposed on a bottom of the guide hole 69. The moving piece 71 is movable only in the front-rear direction X on the bottom of the guide hole 69. A tactile sensor 73 is attached to the moving piece 71. The tactile sensor 73 is attached to an upper surface of the moving piece 71.

The tactile sensor 73 has a detection surface 75 capable of detecting a force applied to each of three axes orthogonal to each other. The tactile sensor 73 is attached to the moving piece 71 in a posture in which the detection surface 75 is directed upward. The guide 67 is attached to the detection surface 75. A bottom of the guide 67 is attached to the detection surface 75. The tactile sensor 73 can detect a force applied to the guide 67 in each of the three axial directions. The tactile sensor 73 detects forces applied in the front-rear direction X, the width direction Y, and the vertical direction Z. The tactile sensor 73 outputs electrical signals respectively corresponding to the detected forces in the three axial directions.

In the finger portion 61, a lateral hole 77 is provided in the front-rear direction X from the guide hole 69. The lateral hole 77 penetrates to the palm portion 59. In the palm portion 59, a servomotor 79 is provided at a position corresponding to an end of the lateral hole 77. The servomotor 79 includes an encoder 81. The encoder 81 detects a rotational position (rotation angle) of a rotation shaft of the servomotor 79, and outputs the rotational position as position information in the form of an electric signal. A ball screw 83 is inserted into the lateral hole 77. A side of one end of the ball screw 83 is connected to the rotation shaft of the servomotor 79. The moving piece 71 is screwed to a side of the other end of the ball screw 83. When the servomotor 79 is rotationally driven, the ball screw 83 is rotated, and the moving piece 71 moves in the front-rear direction X along the guide hole 69. As a result, the guide 67 moves in the front-rear direction X.

As illustrated in FIG. 9, the palm portion 59 includes a pusher 87. The pusher 87 includes one of the guides 67. The pusher 87 has the same configuration as the configuration for driving the guide 67 of the finger portion 61 except for a pusher arm 89 and a guide hole 91.

That is, the pusher 87 includes the tactile sensor 73, the lateral hole 77, the ball screw 83, the servomotor 79, the encoder 81, and the pusher arm 89. One end side of the lateral hole 77 penetrates a side surface on the finger portion 61 side. The guide hole 91 is provided on a side of the finger portion 61 of the lateral hole 77. The guide hole 91 is larger in the vertical direction Z than the lateral hole 77. A part of the pusher arm 89 is inserted into the guide hole 91 in a manner movable in the front-rear direction X. A side of the other end of the lateral hole 77 is closed within the palm portion 59. The servomotor 79 is disposed on the side of the other end of the lateral hole 77. The servomotor 79 includes the encoder 81. The side of the one end of the ball screw 83 is connected to the rotation shaft of the servomotor 79. The pusher arm 89 is screwed to side of the other end of the ball screw 83. The pusher arm 89 includes the tactile sensor 73 on the opposite side of the servomotor 79 in the front-rear direction X. The guide 67 is attached to the detection surface 75 of the tactile sensor 73.

Each of the above-described guides 67 is configured to be movable by a predetermined distance in the front-rear direction X. Each of the above-described guides 67 is movable, for example, by a distance of about 5 mm in the front-rear direction X.

The first hand 19 includes the three guides 67 on the upper surface. The first hand 19 holds the substrate W in a state where the lower surface of the substrate W is separated upward from the upper surfaces of the finger portions 61. Specifically, the outer peripheral surface of the substrate W is grasped by the three guides 67, and the lower surface of the substrate W is held in a state floating from the upper surfaces of the finger portions 61. The first hand 19 holds the substrate W in a state of being in contact only with the outer peripheral surface of the substrate W. The first hand 19 moves the three guides 67 toward the outer peripheral surface of the substrate W to grasp the outer peripheral surface of the substrate W with the three guides 67, and holds the substrate W in a state of being separated from the upper surfaces of the finger portions 61.

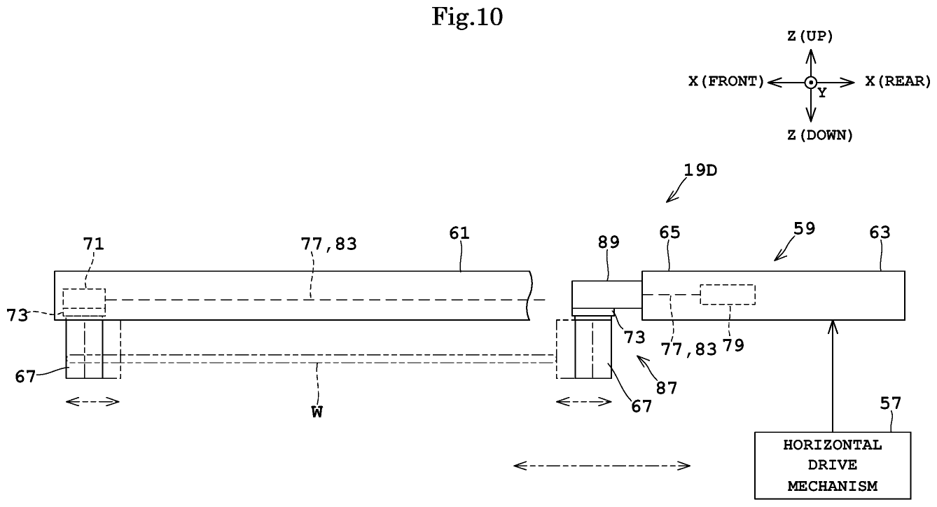

While the first hand 19 includes the three guides 67 on the upper surface, the first hand 19 may be configured as illustrated in FIG. 10. FIG. 10 is a side view of the upper pickup hand according to the embodiment.

Unlike the first hand 19, a first hand 19D includes three guides 67 attached to a lower surface of the hand. Specifically, each of the two finger portions 61 has one of the guides 67 on the lower surface on the side of the distal end. The palm portion 59 includes one of the guides 67 on the lower surface on the side of the distal end. The first hand 19D is referred to as “upper pickup hand”. The first hand 19D having a structure of the upper pickup hand, holds the substrate W by approaching from above and then lifting the substrate W upward.

The first hand 19D drives the three guides 67 with the same configuration except that attachment surfaces for the guide 67 are different from those of the first hand 19. Therefore, a detailed description of the drive mechanism will be omitted.

Each of the guides 67 described above is preferably made of, for example, PBI (polybenzimidazole). This is because PBI has high heat resistance, excellent chemical resistance, and robustness. However, each of the guides 67 may be made of a different material. Examples of the different material include a fluorine resin such as PTFE (polytetrafluoroethylene) and PFA (perfluoroalkoxy alkane).

### <8. Control System>

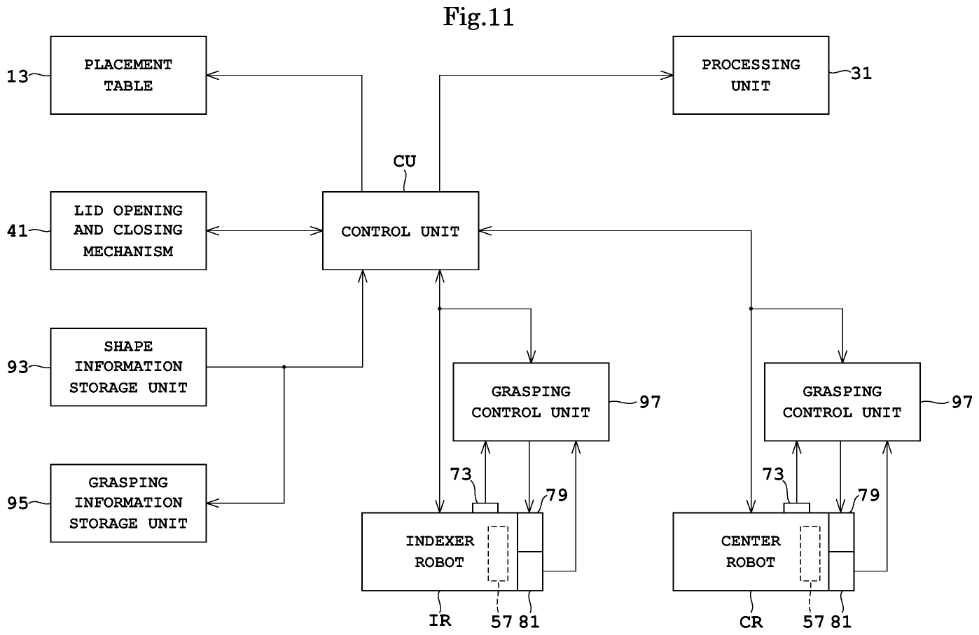

A control system of the substrate processing device 1 described above will be described with reference to FIG. 11. FIG. 11 is a block diagram illustrating the control system.

The substrate processing device 1 is integrally controlled by a control unit CU. The control unit CU includes a CPU and a memory. The control unit CU transports the substrate W to the processing unit 31 on the basis of a recipe defining a processing procedure, conditions, and the like of the substrate W and performs processing.

A shape information storage unit 93 stores the shape information for each substrate W obtained by the substrate sensor 45 in association with the substrate W. The shape information includes a thickness of the substrate W. The shape information includes warpage of the substrate W. In the shape information storage unit 93, the shape information is referred to by the control unit CU.

A grasping information storage unit 95 stores a center position of the substrate W according to the positions of the guides 67 when the substrate W is held by the first hand 19. The center position of the substrate W is acquired by the control unit CU via a grasping control unit 97 to be described later and written in the grasping information storage unit 95 by the control unit CU.

The grasping information storage unit 95 also stores pieces of grasping information in advance according to the shape of the substrate W. The grasping information is associated with each piece of the shape information of the substrate W. The grasping information includes the biasing forces applied to the guides 67. The grasping information is information related to the biasing forces applied to the guides 67 by the servomotor 79. The biasing forces applied from the guides 67 to the substrate W and the torque applied from the servomotor 79 to the ball screw 83 are smaller as the substrate W is thinner, for example. These biasing forces and torques are smaller as the substrate W warps, for example. These biasing forces and torques are larger as the substrate W is not warped and is thicker, for example.

The grasping information includes biasing forces and torques in a case where the substrate W of various shapes is actually held by the first hand 19 in advance, and where the substrate W can be held in a state where the substrate W and the guide 67 are not damaged and the substrate W does not fall. The grasping information may be stored in advance in a separate device (not illustrated) and downloaded from a host computer (not illustrated) via a network.

The processing unit 31 includes the back surface cleaning unit SSR and the like. The processing unit 31 includes the placement unit 47A and the placement unit 47B described above. The processing of the processing unit 31 is controlled by the control unit CU. The control unit CU stores in advance that which processing unit 31 includes the placement unit 47A and which processing unit 31 includes the placement unit 47B.

The indexer robot IR and the center robot CR are controlled by the control unit CU. Movement of the indexer robot IR and the center robot CR in the front-rear direction X, the width direction Y, and the vertical direction Z is operated by the control unit CU. Movement of the first hands 19 and 33 and the second hands 21 and 35 in the front-rear direction X is operated by the control unit CU via the horizontal moving mechanism 57.

The grasping control unit 97 independently operates the movement of each of the three guides 67. The grasping control unit 97 is operated by the control unit CU. The grasping control unit 97 operates each of the servomotors 79 based on an instruction from the control unit CU to independently move the three guides 67. At that time, the grasping control unit 97 operates the servomotor 79 according to the position information from the encoder 81. The grasping control unit 97 operates a drive current to the servomotor 79. The grasping control unit 97 can detect the drive current supplied to the servomotor 79.

When the tactile sensor 73 detects that the guide 67 abuts on the outer peripheral surface of the substrate W, the grasping control unit 97 adjusts the biasing force of the guide 67 to the outer peripheral surface of the substrate W according to the shape information from the shape information storage unit 93, and grasps the substrate W. At this time, the guide 67 does not necessarily move from the side of the outer peripheral surface to the side of the center of the substrate W. That is, the guide 67 only increases the torque of the servomotor 79 to strengthen the biasing force to the outer peripheral surface of the substrate W, and may not move toward the center of the substrate W.

In a case where the first hand 19 holds the substrate W by holding the substrate W by the three guides 67, the control unit CU calculates the center position of the substrate W on the basis of moving distances of the guides 67 at that time, and stores the center position in the grasping information storage unit 95. The center position of the substrate W when the substrate W is grasped stored in the grasping information storage unit 95 is generally shifted from the center position of the substrate W in a design of the first hand 19. The grasping information that is the center position of the substrate W stored in the grasping information storage unit 95 is referred to by the control unit CU, and the control unit CU operates the indexer robot IR so as to correct the center position when placing the substrate W on the transfer unit 15, and transfers the substrate W to the transfer unit 15.

The control system of the indexer robot IR described above also includes the center robot CR. That is, the control system of the center robot CR includes the grasping control unit 97. Similarly to the indexer robot IR, the center robot CR calculates the center position of the substrate W when the substrate W is grasped by the three guides 67, and the calculated center position is stored in the grasping information storage unit 95. The control unit CU refers to the center position of the substrate W stored in the grasping information storage unit 95, and operates the center robot CR in order to transfer the substrate W to and from each of the processing units 31.

### <9. Operation Flow>

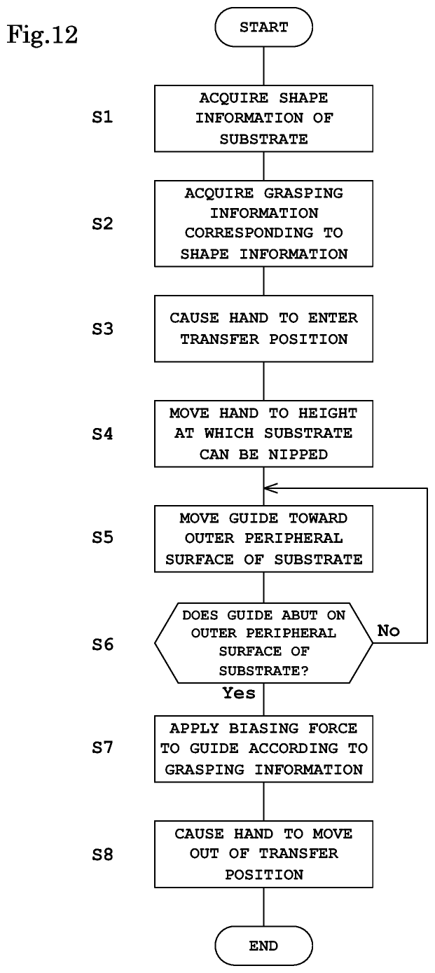

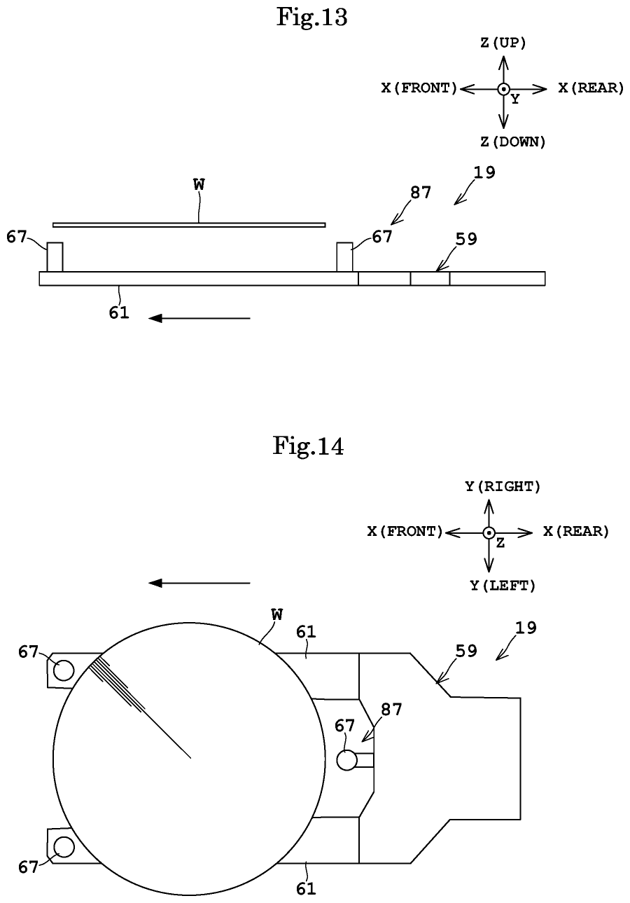

A transport operation of the substrate W by the indexer robot IR in the substrate processing device 1 will be described with reference to FIGS. 12 to 22. FIG. 12 is a flowchart for explaining an operation related to transportation. FIGS. 13, 15, 17, 19, 21, and 22 are schematic views for explaining the operation as viewed from the side. FIGS. 14, 16, 18, and 20 are schematic views for explaining the operation as viewed from a plane.

In the following description, an operation of receiving the substrate W from the carrier C will be described as an example.

### Step S1

The shape information of the substrates W is acquired. When the lid CL is removed from the carrier C by the detachable unit 43, the control unit CU acquires the shape information of each of the substrates W by the substrate sensor 45. The control unit CU stores the acquired shape information in the shape information storage unit 93 in association with each of the substrates W.

### Step S2

The grasping information corresponding to the shape information is acquired. The control unit CU reads, from the grasping information storage unit 95, the grasping information corresponding to the shape information of the substrate W to be received by the first hand 19.

### Step S3

As illustrated in FIGS. 13 and 14, the control unit CU operates the horizontal moving mechanism 57 of the indexer robot IR to cause the first hand 19 to enter the transfer position in the carrier C. Since the first hand 19 is a lower pickup hand that receives the substrate W so as to lift the substrate W from below, the first hand 19 enters below the position where the substrate W to be received is placed. At this time, the control unit CU preferably expands the three guides 67 of the first hand 19 at a maximum. In other words, the guides 67 of the finger portions 61 are moved to the front side X as much as possible, and the guide 67 of the pusher 87 is moved to the rear side X as much as possible. As a result, even if the placement position of the substrate W is greatly shifted, the substrate W can be reliably received by the first hand 19.

### Step S4

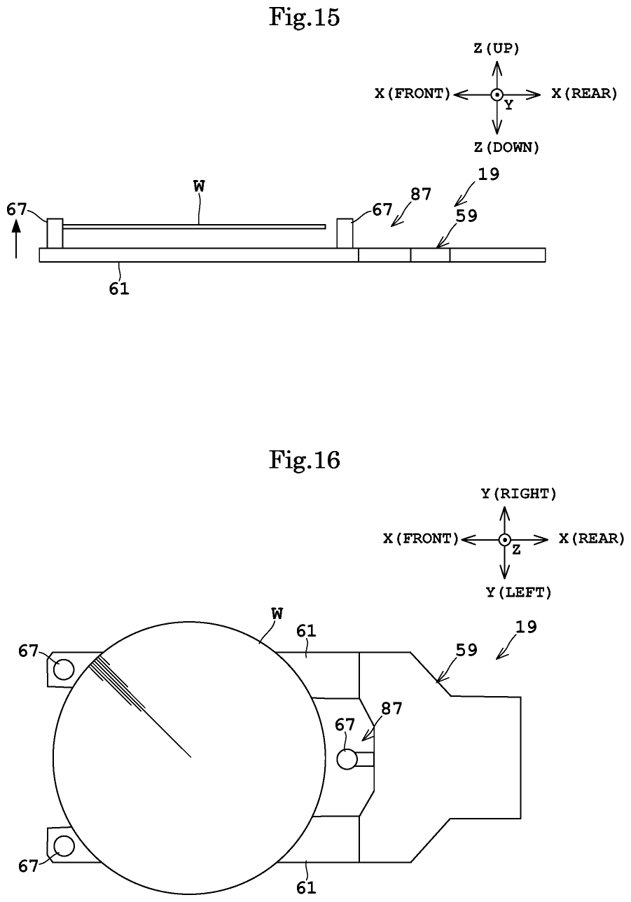

As illustrated in FIGS. 15 and 16, the control unit CU moves the substrate W to a height at which the substrate W can be grasped by the first hand 19. Specifically, the control unit CU operates the indexer robot IR to raise the first hand 19 in the vertical direction Z so that the substrate W is positioned below an upper end of the guides 67 and above the upper surfaces of the finger portions 61.

### Step S5

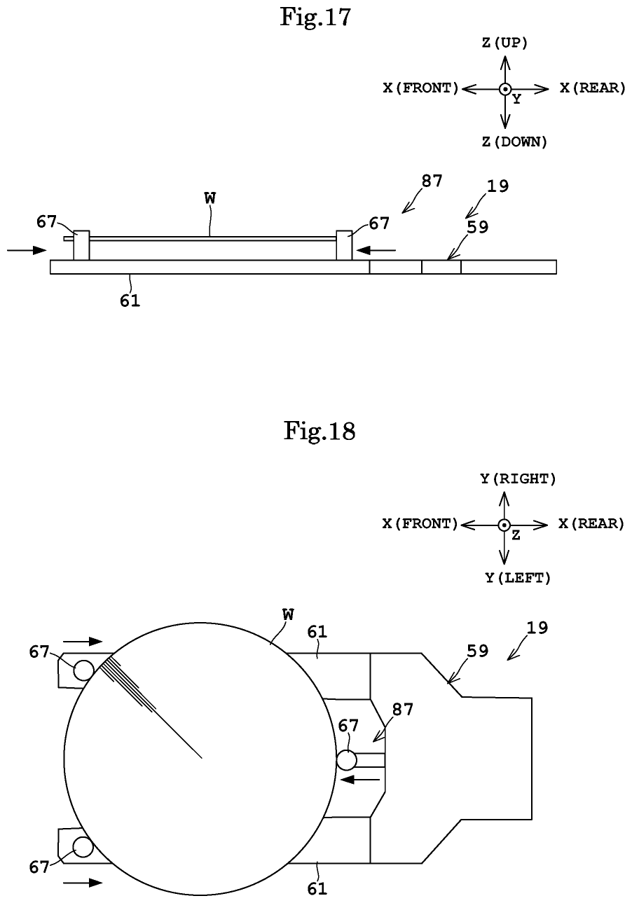

As illustrated in FIGS. 17 and 18, the control unit CU operates the grasping control unit 97 to move the three guides 67 of the first hand 19 toward the outer peripheral surface of the substrate W.

### Step S6

The control unit CU branches the processing depending on whether or not each of the guides 67 abuts on the outer peripheral surface of the substrate W. Step S5 is repeated until each of the guides 67 abuts on the outer peripheral surface of the substrate W. In other words, the movement of each guide 67 toward the outer peripheral surface of the substrate W is maintained until each guide 67 abuts on the outer peripheral surface of the substrate W. Whether or not each guide 67 abuts on the outer peripheral surface of the substrate W is determined by a signal from the corresponding tactile sensor 73.

The control unit CU can detect that each guide 67 abuts on the outer peripheral surface of the substrate W by the corresponding tactile sensor 73. Therefore, the control unit CU can move each guide 67 at a high speed until each guide 67 abuts on the outer peripheral surface of the substrate W. As a result, the time until the first hand 19 holds the substrate W can be shortened.

### Step S7

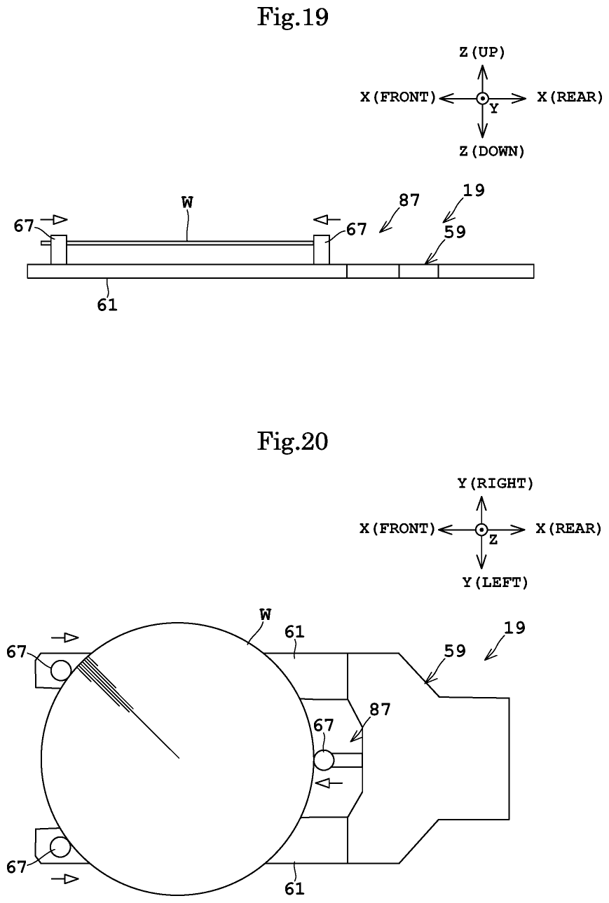

When each guide 67 abuts on the outer peripheral surface of the substrate W, the following operation is performed. As illustrated in FIGS. 19 and 20, the control unit CU applies a biasing force (indicated by a white arrow in the drawing) to the guide 67 according to the grasping information.

Specifically, the control unit CU refers to the grasping information storage unit 95 and reads a piece of the grasping information corresponding to the substrate W. The control unit CU operates the grasping control unit 97 according to the read piece of the grasping information to bias the guide 67. As a result, the guide 67 is pressed against the outer peripheral surface of the substrate W. Since each of the guides 67 is biased based on the grasping information, the substrate W can be supported by each of the guides 67 so that the substrate W does not fall on the finger portion 61. In addition, since each of the guides 67 is biased based on the grasping information, it is possible to suppress the occurrence of damage in the substrate W and the guides 67.

### Step S8

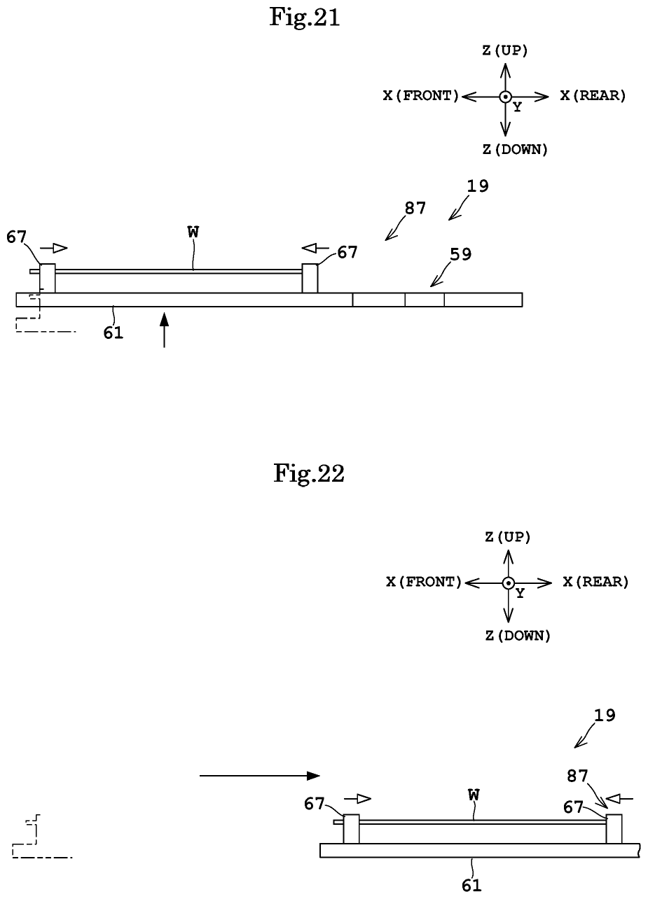

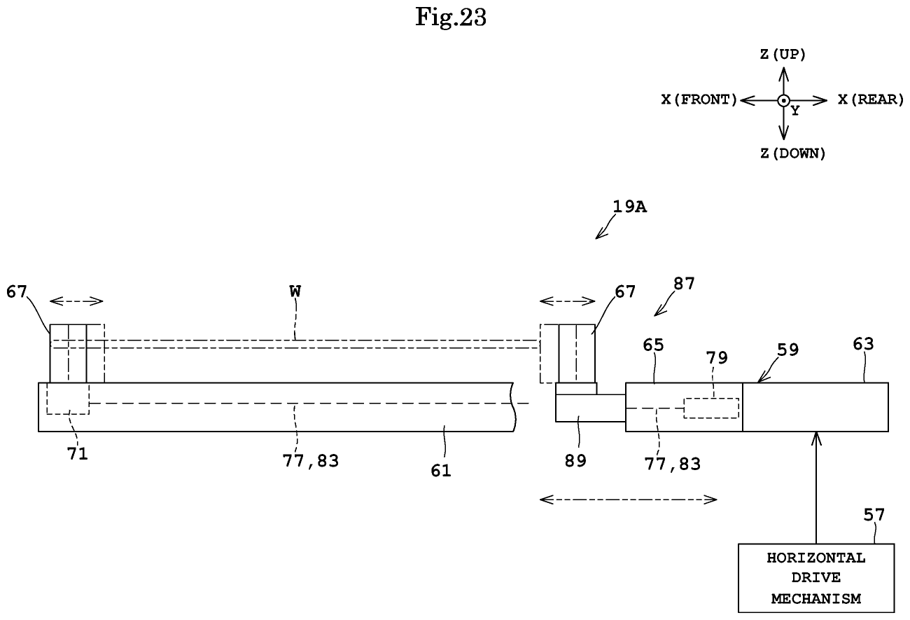

As illustrated in FIG. 21, the control unit CU operates the indexer robot IR to move the first hand 19 in the vertical direction Z by a predetermined distance. Next, as illustrated in FIG. 22, the control unit CU operates the horizontal moving mechanism 57 of the indexer robot IR to cause the first hand 19 to move out of the transfer position in the carrier C. Note that the above-described biasing force (indicated by the white arrow in the drawing) is maintained until the substrate W is transferred to the transport destination.

According to the first embodiment, when the substrate W is held by the first hand 19, the control unit CU operates the servomotor 79 to move each of the guides 67 to the outer peripheral surface of the substrate W. When the tactile sensor 73 detects that each guide 67 abuts on the outer peripheral surface of the substrate W, the control unit CU causes the servomotor 79 to adjust the biasing force by each guide 67 to the outer peripheral surface of the substrate W according to the shape of the substrate W. Therefore, the grasping force can be adjusted according to the shape of the substrate W such as warpage and a thickness of the substrate W. As a result, it is possible to prevent the substrate W from being damaged during transportation regardless of the shape of the substrate W. Further, it is also possible to prevent each of the guides 67 from being damaged.

In the first embodiment, all the guides 67 are movable, and the biasing force is adjusted for each of the three guides 67. Therefore, when the substrate W is grasped, the distance by which the lower surface of the substrate W slides in the horizontal direction at the place where the substrate W is placed can be shortened. As a result, even when the center of the substrate W at the position where the substrate W is placed is shifted from the center of the first hand 19 at the transfer position where the first hand 19 has advanced, the shift of the center position of the substrate W at the time of grasping the substrate W is minimized. Therefore, it is possible to suppress particles generated as the substrate W is grasped.

The correspondence between the first embodiment described above and the configuration of the present invention is as follows.

The indexer robot IR and the center robot CR correspond to a “substrate transport apparatus” in the present invention. Each of the guides 67 corresponds to a “movable guide” in the present invention. The moving piece 71, the servomotor 79, and the ball screw 83 correspond to an “advance and retreat drive mechanism” in the present invention. The tactile sensor 73 corresponds to an “outer peripheral surface detection unit” in the present invention. The control unit CU and the grasping control unit 97 correspond to a “control unit” in the present invention. The processing unit 31 and the back surface cleaning unit SSR correspond to a “processor” in the present invention.

The present invention is not limited to the above embodiment, and can be modified as follows.

(1) In the first embodiment described above, the tactile sensor 73 is employed as the outer peripheral surface detection unit. However, the present invention is not limited to such a configuration. That is, as long as it can be detected that the guide 67 abuts on the outer peripheral surface of the substrate W, a different detection unit may be employed. As the outer peripheral surface detection unit, for example, a proximity sensor, a reflective sensor, or the like may be employed.

(2) In the first embodiment described above, the tactile sensor 73 is provided at a portion where the hand 19 is attached to the finger portion 61. However, the present invention is not limited to such an aspect. That is, the tactile sensor 73 may be provided on the side surface of the guide 67. In this case, the detection surface 75 is preferably directed toward the outer peripheral surface side of the substrate W. This is because the detection sensitivity of the tactile sensor 73 can be increased.

(3) In the first embodiment described above, the guides 67 has a columnar shape, but the present invention is not limited to such an aspect. That is, the shape of the guides 67 is not limited.

(4) In the first embodiment described above, the first hand 19 of the indexer robot IR has been described as an example. However, the present invention can also be applied to the second hand 21 of the indexer robot IR and to the first hand 33 and the second hand 35 of the center robot CR.

(5) In the first embodiment described above, the configuration in which all the three guides 67 are movable is employed. However, the present invention is not limited to such a configuration. That is, for the configuration of the present invention, it is sufficient as long as at least one guide 67 is movable.

(6) In the first embodiment described above, a configuration including the three guides 67 is employed. However, the present invention is not limited to such a configuration. That is, the present invention may include at least two or four or more guides 67. For example, the first hand 19 including the two guides 67 may include one finger portion having an I-shaped shape in plan view, and may be configured by one arc-shaped guide 67 corresponding to the outer edge shape of the substrate W on the side of the distal end and the pusher 87 on the side of the proximal end.

(7) In the first embodiment described above, the advance and retreat drive mechanism is configured to move the guide 67 with the moving piece 71, the servomotor 79, and the ball screw 83. However, the present invention is not limited to such a configuration. For example, a configuration including a wire having a side of one end connected to a spring, a guide fixedly attached to a part of the wire, and a drive unit that moves the wire in the front-rear direction X by winding a side of the other end of the wire may be employed.

(8) In the first embodiment described above, the guide 67 is driven to advance and retreat in the front-rear direction X with respect to the finger portion 61, but the present invention is not limited to such a configuration. For example, the guide 67 may be fixedly attached to the finger portion 61, and the finger portion 61 may be attached to the finger portion attachment portion 65 such that the finger portion 61 is movable forward and backward in the front-rear direction X in the finger portion attachment portion 65. As a result, the movable portion can be disposed outside the outer peripheral surface of the substrate W, which is advantageous in terms of cleanliness.

(9) In the first embodiment described above, the tactile sensor 73 that detects that the guide 67 abuts on the outer peripheral surface of the substrate W is provided. However, the present invention does not necessarily require the tactile sensor 73. That is, when the guide 67 is moved toward the outer peripheral surface of the substrate W by the servomotor 79, the control unit CU may move the guide 67 with a weak driving force, and determine that the guide 67 abuts on the outer peripheral surface of the substrate W when the movement is stopped. Thereafter, the control unit CU may adjust the biasing force to the substrate W by the guide 67 according to the position information from the encoder 81. Note that, it is possible to shorten the time until the substrate W by, as in the first embodiment described above, adjusting the biasing force after detecting the outer peripheral surface of the substrate W using the tactile sensor 73.

(10) In the first embodiment described above, the biasing force applied to the substrate W was adjusted according to the shape of the substrate W. However, the present invention is not limited to such an aspect. The biasing force may be increased, for example, when the transport speed at the time of transportation of the substrate W is high, when the substrate W is rapidly accelerated and decelerated at the time of transportation of the substrate W, or when the substrate W is rapidly turned or reversed at the time of transportation of the substrate W.

### Second Embodiment

Next, a second embodiment of the present invention will be described with reference to the drawings.

FIG. 23 is a side view of a hand in the substrate processing device according to the second embodiment. Note that the configuration and the like of the substrate processing device 1 are similar to those of the first embodiment described above. Therefore, a detailed description of the substrate processing device 1 will be omitted.

In the following, similarly to the first embodiment described above, the configuration of the first hand 19 included in the indexer robot IR will be described as an example. The hand according to the second embodiment is indicated by a first hand 19A.

### <1. Details of Hand>

The first hand 19A includes the two finger portions 61 and the one palm portion 59. The two finger portions 61 respectively includes the guides 67. The one palm portion 59 includes one guide 67. The first hand 19A includes the three guides 67.

The three guides 67 move in the front-rear direction X with a configuration similar to that of the first embodiment described above. That is, each of the guides 67 is moved by the moving piece 71, the lateral hole 77, the servomotor 79, and the ball screw 83. However, the first hand 19A in the second embodiment does not include the tactile sensor 73.

### <2. Control System>

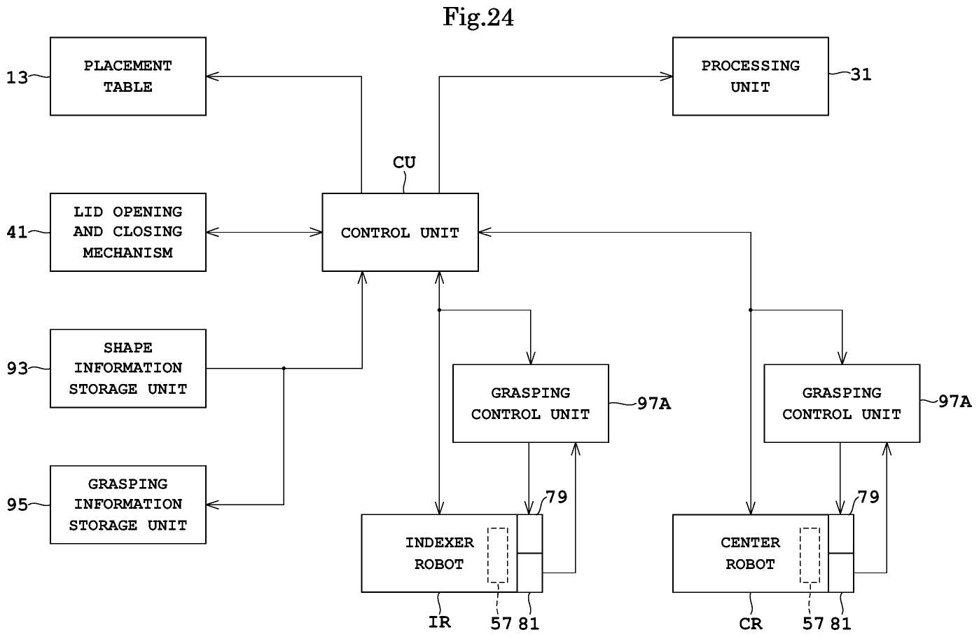

A control system will be described with reference to FIG. 24. FIG. 24 is a block diagram illustrating a control system of the substrate processing device according to the second embodiment.

The same reference numerals as those of the above-described the first embodiment are given to the configurations common to the above-described the first embodiment, and a detailed description thereof will be omitted.

The control unit CU operates the indexer robot IR. In particular, the operation of grasping the substrate W by the first hand 19A is performed by a grasping control unit 97A.

The grasping control unit 97A is connected to the servomotor 79 and the encoder 81. The grasping control unit 97A operates the servomotor 79 based on an instruction from the control unit CU to move the three guides 67. At that time, the grasping control unit 97A operates the servomotor 79 according to the position information from the encoder 81. The grasping control unit 97A can detect the drive current supplied to the servomotor 79 as drive current information. The grasping control unit 97A determines that the guide 67 abuts on the outer peripheral surface of the substrate W based on one or both of the position information and the drive current information.

That is, when the guide 67 abuts on the outer peripheral surface of the substrate W, the movement of the guide 67 is temporarily hindered. Therefore, displacement of the position information from the encoder 81 temporarily stops. Even if the guide 67 abuts on the outer peripheral edge of the substrate, it is necessary to increase the torque of the servomotor 79 in order to further move the guide 67 toward the outer peripheral surface of the substrate W. Therefore, the drive current to the servomotor 79 increases, and the drive current information is displaced. Therefore, by monitoring one or both of the position information and the drive current information, it is possible to accurately determine that the guide 67 abuts on the outer peripheral surface of the substrate W. After the guide 67 abuts on the outer peripheral surface of the substrate W, the grasping control unit 97A adjusts the biasing force of the guide 67 to the outer peripheral surface of the substrate W according to the shape information from the shape information storage unit 93 and grasps the substrate W.

The correspondence between the second embodiment described above and the configuration of the present invention is as follows.

The grasping control unit 97A corresponds to an “outer peripheral surface detection unit” in the present invention. The control unit CU and the grasping control unit 97A correspond to a “control unit” in the present invention. The servomotor 79 corresponds to a “motor” in the present invention. The grasping control unit 97A corresponds to a “drive circuit” and a “drive current detection unit” in the present invention. The encoder 81 corresponds to a “position information detection unit” in the present invention.

According to the second embodiment, the control unit CU determines that the guide 67 abuts on the outer peripheral surface of the substrate W based on at least one of the drive current information from the grasping control unit 97A and the position information from the encoder 81. Therefore, it is not necessary to provide the tactile sensor 73 or the like that detects abutment between the guide 67 and the outer peripheral surface of the substrate W. As a result, it is possible to simplify the structure and to suppress the cost.

The present invention is not limited to the above embodiment, and can be modified as follows.

In the second embodiment described above, (3) to (8) and (10) excluding (1) and (2) in the modifications of the first embodiment may be adopted. In addition, similarly to (9) in the modification of the first embodiment, the biasing force to the substrate W may be adjusted without detecting that the guide 67 abuts on the outer peripheral surface of the substrate W.

### Third Embodiment

Next, a third embodiment of the present invention will be described with reference to the drawings.

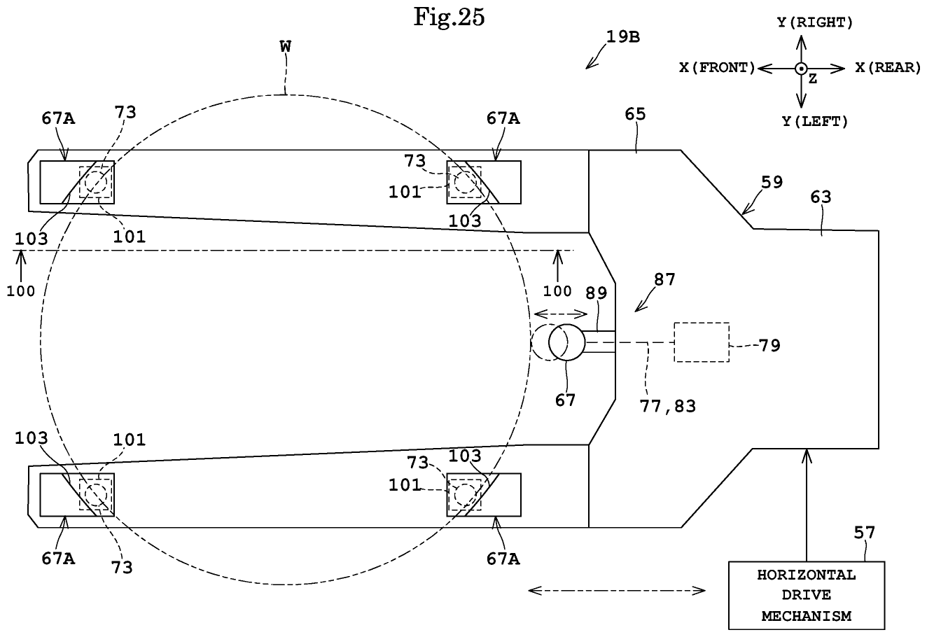

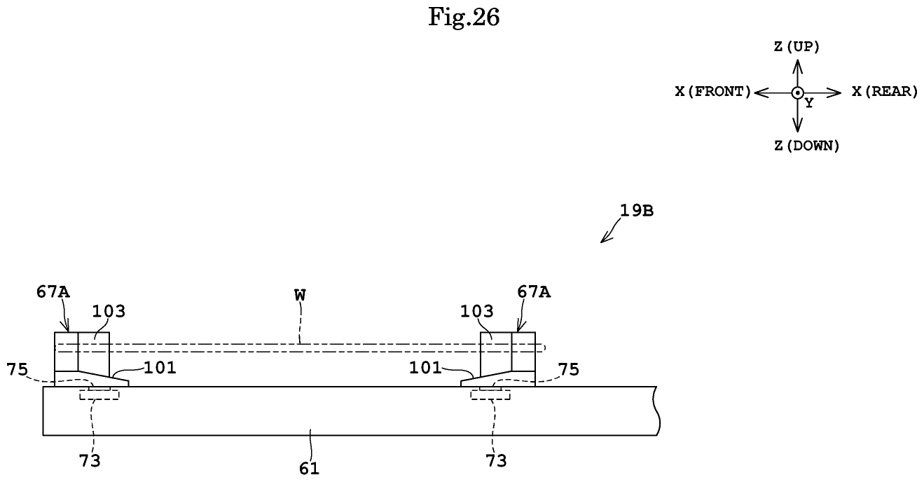

FIG. 25 is a plan view of a hand of the substrate processing device according to the third embodiment. FIG. 26 is a view taken along a line indicated by arrows 100-100 viewed in a direction of the arrows in FIG. 25. Note that the configuration and the like of the substrate processing device 1 are similar to those of the first embodiment described above, and thus detailed description thereof will be omitted.

In the following, similarly to the first and the second embodiment described above, the configuration of the first hand 19 included in the indexer robot IR will be described as an example. The hand according to the third embodiment is indicated by a first hand 19B.

### <1. Details of Hand>

The first hand 19B is different from the first and second embodiments in the configuration of the finger portion 61. That is, the finger portion 61 includes the guides 67A on sides of both ends of the front side X and the rear side X, respectively. Each of the guides 67A is a fixed type that is not movable. Each guide 67A does not move in the front-rear direction X in the finger portion 61.

The guide 67A includes an inclined surface 101 and a restricting portion 103. The inclined surface 101 is provided so as to be lowered toward the side of the center of the substrate W. In other words, the inclined surface 101 is provided so as to be higher outward from the outer peripheral surface of the substrate W. The restricting portion 103 is erected along the outer peripheral surface of the substrate W. The restricting portion 103 is preferably provided such that a portion facing the outer peripheral surface of the substrate W in plan view has the same shape as the shape of the corresponding outer peripheral surface of the substrate W. This is because the substrate W can be stably held although an area of contact increases. The four guides 67A are disposed slightly outside the outer shape of the substrate W in plan view.

The guide 67A is attached to the upper surface of the finger portion 61 with the tactile sensor 73 interposed therebetween. The tactile sensor 73 is attached to the guide 67A such that the force applied to the guide 67A is transmitted to the detection surface 75.

In the first hand 19B described above, after the substrate W is placed on the inclined surface 101 of the guide 67A, the outer peripheral surface of the substrate W is biased to the front side X by the guide 67 of the pusher 87. As a result, the outer peripheral surface of the substrate W located in the front side X slides up the inclined surface 101, is pressed against the restricting portion 103, and is grasped between the guide 67 of the pusher 87 and the two guides 67A. As a result, the substrate W is held by the first hand 19B.

The tactile sensor 73 of the guide 67A detects that the substrate W is placed. That is, the tactile sensor 73 only needs to detect the force in the vertical direction Z. A signal from the tactile sensor 73 of the guide 67A is used by the grasping control unit 97 to determine whether or not the substrate W is present. When the grasping control unit 97 determines that there is no substrate W, the determination is transmitted to the control unit CU. Furthermore, the grasping control unit 97 can determine the placement posture of the substrate W from degrees of application of forces at the four guides 67A. When the inclination is large, it may be determined that there is no substrate W since there is an adverse effect during transportation of the substrate W.

### <2. Operation Flow>

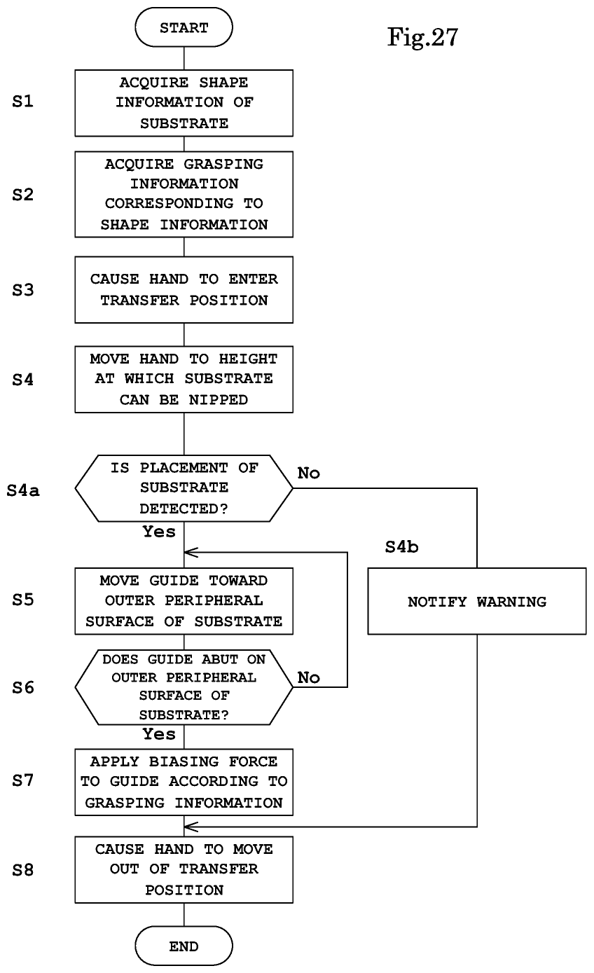

An operation will be described with reference to FIG. 27. FIG. 27 is a flowchart for explaining an operation related to transportation. Note that the same steps as those in the operation flow of FIG. 12 in the first embodiment are denoted by the same reference numerals, and a detailed description thereof will be omitted.

### Step S4a

The processing is branched depending on whether or not the placement of the substrate W is detected. The grasping control unit 97 can determine the presence or absence of the substrate W including a posture defect in which the substrate W is placed in an inclined manner based on an output of the tactile sensor 73 of each guide 67A. When the grasping control unit 97 detects the substrate W, the control unit CU proceeds the processing to Step S5. On the other hand, when the grasping control unit 97 does not detect the substrate W, the process proceeds the processing to step S4b.

### Step S4b

The control unit CU notifies of a warning. Specifically, the control unit CU issues a warning sound from a speaker that is not illustrated, displays a warning on a display that is not illustrated, or blinks a warning lamp that is not illustrated. Thus, an operator of the device can recognize occurrence of an abnormality.

According to the third embodiment, the tactile sensor 73 can detect that the substrate W is correctly placed on the inclined surface 101 of the guide 67A. Therefore, the presence or absence of the substrate W can be accurately detected.

The correspondence between the third embodiment described above and the configuration of the present invention is as follows.

The tactile sensor 73 corresponds to a “placement detection unit” in the present invention. The guide 67 of the pusher 87 corresponds to a “movable guide” in the present invention.

The present invention is not limited to the above embodiment, and can be modified as follows.

In the third embodiment described above, (3), (4) to (7) to (10) excluding (1) and (2) in the modifications of the first embodiment may be adopted.

The configuration of the third embodiment may also be adopted in the pass portions 25 and 27 of the transfer unit 15. As a result, it is possible to accurately determine whether or not the substrate W can be normally placed on the pass portions 25 and 27, and whether or not the substrate W is present in the pass portions 25 and 27.

### Fourth Embodiment

Next, a fourth embodiment of the present invention will be described with reference to the drawings.

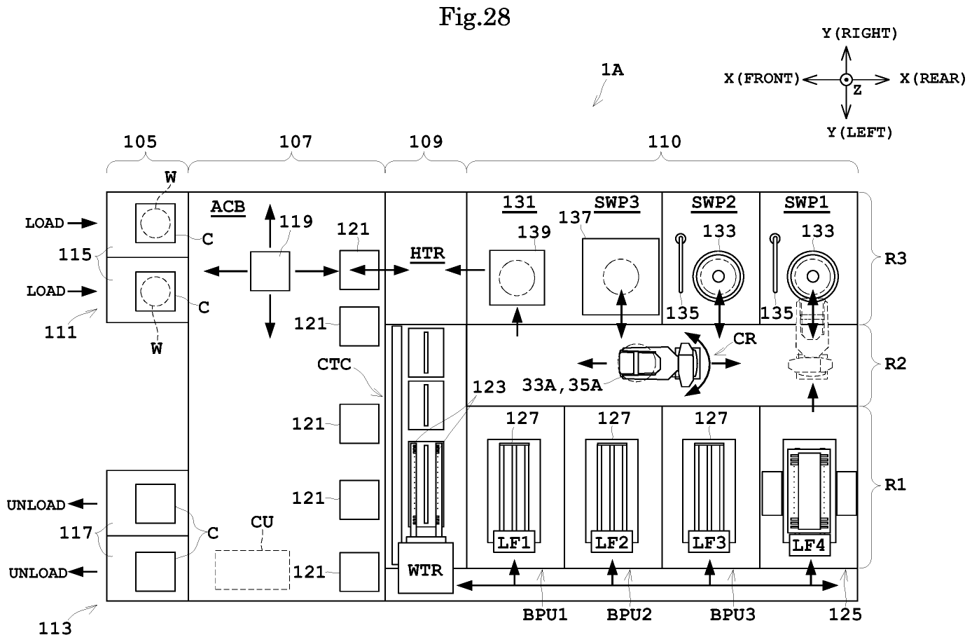

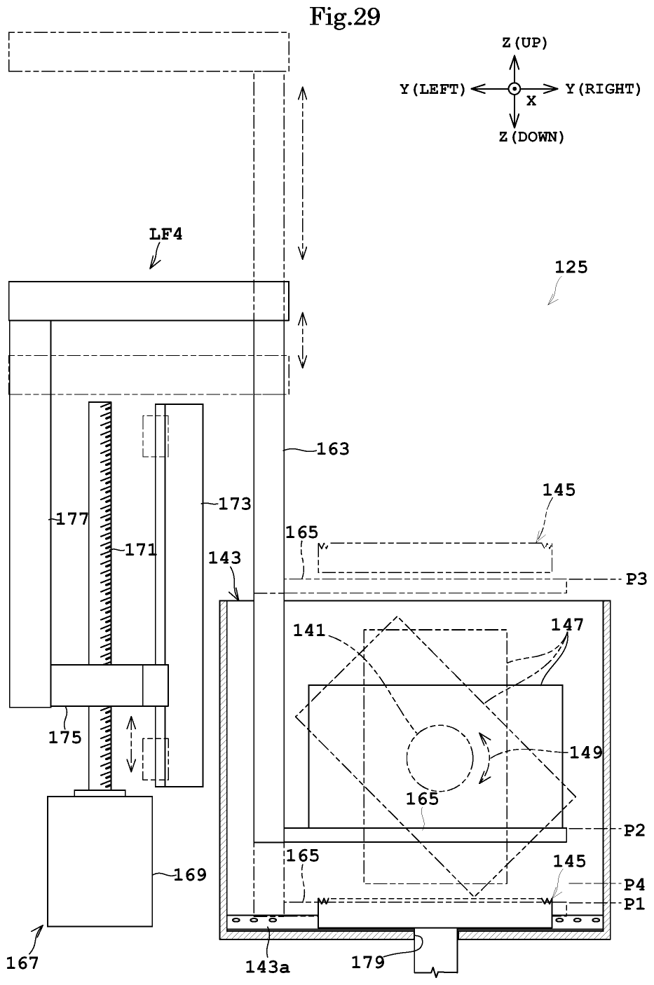

FIG. 28 is a plan view illustrating a schematic configuration of the substrate processing device according to the fourth embodiment. FIG. 29 is a side view of an underwater posture converting unit.

### <1. Overall Configuration>

A substrate processing device 1A includes a carry-in and carry-out block 105, a storage block 107, a transfer block 109, and a processing block 110.

The substrate processing device 1A processes the substrate W. The substrate processing device 1A performs, for example, a chemical liquid treatment, a cleaning treatment, a drying treatment, and the like on the substrate W. The substrate processing device 1 adopts a processing method (so-called hybrid method) having both batch type processing and single wafer processing. The batch type processing collectively processes a plurality of substrates W in the vertical posture. In the single wafer processing method, a single substrate W is processed in the horizontal posture.

### <2. Carry-In and Carry-Out Block>

The carry-in and carry-out block 105 includes a load unit 111 and an unload unit 113. The load unit 111 and the unload unit 113 are disposed in the width direction Y. A plurality of (for example, 25 sheets) substrates W are stacked and stored at constant intervals in a horizontal posture in one carrier C. The carrier C storing unprocessed substrates W is placed on the load unit 111. The load unit 111 includes, for example, two placement tables 115 on which the carrier C is placed. In the carrier C, a plurality of grooves (not illustrated) for accommodating the substrates W one by one with surfaces of the substrates W separated from each other are provided. Examples of the carrier C include a front opening unify pod (FOUP). The FOUP is a closed-type container. The carrier C may be an open-type container or of any type.

The unload unit 113 is disposed on the opposite side of the load unit 111 across the central portion in the width direction Y of the substrate processing device 1A. The unload unit 113 is disposed on the left side Y of the load unit 111. The unload unit 113 places the processed substrates W in the carrier C and unloads the processed substrates W with the carrier C in whole. Similarly to the load unit 111, the unload unit 113 functioning in this manner includes, for example, two placement tables 117 for placing the carrier C. The load unit 111 and the unload unit 113 are also called load ports.

### <3. Storage Block>

The storage block 107 is disposed adjacent to the carry-in and carry-out block 105 on the rear side X. The storage block 107 includes a transport storage unit ACB. The transport storage unit ACB includes a transport mechanism 119 and shelves 121.

The transport mechanism 119 transports the carrier C. A number of the shelves 121 provided for the transport storage unit ACB is more than one. The shelves 121 includes a shelf on which the carrier C is simply temporarily placed and a shelf on which the carrier C is placed for transfer to and from a first transport mechanism HTR. The transport storage unit ACB takes in the carrier C storing the unprocessed substrates W from the load unit 111 and places the carrier C on the shelf 121. The transport storage unit ACB transports and places the carrier C on the transfer shelf 121 according to the schedule that defines an order of processing. The transport storage unit ACB transports and places the carrier C that has been placed on the transfer shelf 121 and has become empty on the shelf 121. The transport storage unit ACB transports the carrier C that has been placed on the transfer shelf 121 and in which the processed substrates W have been stored by the first transport mechanism HTR to the shelf 121, and places the carrier C on the shelf 121. The transport storage unit ACB transports the carrier C placed on the shelf 121 and in which the processed substrates W are stored to the unload unit 113.

### <4. Transfer Block>

The transfer block 109 is disposed adjacent to the storage block 107 on the rear side X. The transfer block 109 includes the first transport mechanism HTR, a transport mechanism CTC, and a second transport mechanism WTR.

The first transport mechanism HTR collectively transports a plurality of substrates W. The first transport mechanism HTR collectively takes out the plurality of substrates W (for example, 25 sheets) from the carrier C placed on the transfer shelf 121 in the transport storage unit ACB, and transports the substrates W to the transport mechanism CTC. The transport mechanism CTC transfers the plurality of substrates W between the first transport mechanism HTR and the second transport mechanism WTR.

The second transport mechanism WTR is configured to be movable between the transfer block 109 and the processing block 110. The second transport mechanism WTR transfers a plurality of unprocessed substrates W to the processing block 110. The second transport mechanism WTR includes a pair of hands 123 that transports a lot.

### <5. Processing Block>

The processing block 110 performs a treatment on the substrate W. The processing block 110 is divided into, for example, the first row R1, the second row R2, and the third row R3 in the width direction Y except for the second transport mechanism WTR.

### <5-1. First Row>

The first row R1 mainly includes batch-type processing units. Specifically, the first row R1 includes a first batch processing unit BPU1, a second batch processing unit BPU2, a third batch processing unit BPU3, and an underwater posture converting unit 125.

The first batch processing unit BPU1 performs, for example, a chemical liquid treatment. The chemical liquid treatment is, for example, a phosphoric acid treatment. In the phosphoric acid treatment, phosphoric acid is used as a treatment liquid. In the phosphoric acid treatment, an etching treatment is performed on the plurality of substrates W. In the etching treatment, for example, a film thickness of a film deposited on the substrate W is chemically etched. The coating is, for example, a nitride film.

The first batch processing unit BPU1 includes a treatment tank 127 and a lifter LF1. The treatment tank 127 stores the treatment liquid. The lifter LF1 moves up and down in the vertical direction Z. Specifically, the lifter LF1 moves up and down between a treatment position corresponding to an interior of the treatment tank 127 and a transfer position corresponding to an upper side of the treatment tank 127. The lifter LF1 holds the plurality of substrates W in the vertical posture. The lifter LF1 transfers the plurality of substrates W to and from the second transport mechanism WTR at the transfer position.

The second batch processing unit BPU2 performs, for example, a chemical liquid treatment. The second batch processing unit BPU2 has the same configuration as that of the first batch processing unit BPU1. That is, the second batch processing unit BPU2 includes the treatment tank 127 and a lifter LF2.

The third batch processing unit BPU3 performs, for example, a pure water cleaning treatment. The third batch processing unit BPU3 has the same configuration similar as those of the first batch processing unit BPU1 and the second batch processing unit BPU2. Specifically, the third batch processing unit BPU3 includes the treatment tank 127 and a lifter LF3. However, pure water is mainly supplied to the treatment tank 127 for the pure water cleaning treatment.

### <5-2. Second Row>

The second row R2 includes center robot CR. The center robot CR includes a first hand 33A and a second hand 35A having configurations similar to those of the first hand 33 and the second hand 35 described above. The first hand 33A and the second hand 35A hold one substrate W. The center robot CR is configured to be movable in the front-rear direction X. The center robot CR is configured to be movable up and down in the vertical direction Z. The center robot CR is configured to be turnable in a horizontal plane including the front-rear direction X and the width direction Y. The first hand 33A and the second hand 35A are configured to be movable forward and backward in the horizontal plane including the front-rear direction X and the width direction Y. The first hand 33A and the second hand 35A receive the substrates W one by one from the underwater posture converting unit 125. The center robot CR passes the substrates W one by one to the third row R3.

### <5-3. Third Row>

The third row R3 mainly includes single-wafer-type processing units. Specifically, the third row R3 includes a first single wafer processing unit SWP1, a second single wafer processing unit SWP2, a third single wafer processing unit SWP3, and a buffer unit 131.

Each of the first single wafer processing unit SWP1 and the second single wafer processing unit SWP2 includes, for example, a rotation processing unit 133 and a nozzle 135. The rotation processing unit 133 rotationally drives the substrate W in the horizontal plane. The nozzle 135 supplies a treatment liquid to the substrate W. The treatment liquid is, for example, isopropyl alcohol (IPA) or pure water. For example, the first single wafer processing unit SWP1 and the second single wafer processing unit SWP2 perform a cleaning treatment on the substrate W with pure water, and then perform a preliminary drying treatment with IPA.

The third single wafer processing unit SWP3 includes, for example, a supercritical fluid chamber 137. The supercritical fluid chamber 137 performs, for example, a drying treatment with a supercritical fluid. The fluid used at this time is, for example, carbon dioxide. The supercritical fluid chamber 137 brings the treatment liquid into a supercritical state to treat the substrate W. The supercritical state is obtained by bringing a fluid to a critical temperature and a critical pressure that are inherent in the fluid. Specifically, when the fluid is carbon dioxide, the critical temperature is 31° C. and the critical pressure is 7.38 MPa. In the supercritical state, a surface tension of the fluid is zero. Therefore, the pattern of the substrate W is not affected by the gas-liquid interface. Therefore, pattern collapse on the substrate W hardly occurs.

The buffer unit 131 includes, for example, a plurality of placement shelves 139. At least one lot of substrates W can be placed on the plurality of placement shelves 139. Since the first transport mechanism HTR can collectively take out a plurality of substrates W, the load on the first transport mechanism HTR can be reduced as compared with a case where the substrates W are taken out one by one. The buffer unit 131 can be accessed from a plurality of different directions in the horizontal direction. The center robot CR accesses the buffer unit 131 to place the substrate W from a side of the second row R2 toward the right side Y. The first transport mechanism HTR accesses the buffer unit 131 to receive one lot of substrates W from the front side X toward the rear side X.

In the first single wafer processing unit SPW1, the second single wafer processing unit SWP2, and the third single wafer processing unit SWP3 described above, similar processors are preferably stacked in multiple stages in the vertical direction Z. As a result, the throughput can be improved.

### <6. Underwater Posture Converting Unit>

Here, the underwater posture converting unit 125 will be described. FIG. 29 is a side view of the underwater posture converting unit.

The underwater posture converting unit 125 includes a posture converting unit 141, an immersion tank 143, a lifter LF4, and a pusher 145. The posture converting unit 141 includes an in-tank carrier 147 and a rotation mechanism 149.

The in-tank carrier 147 stores a plurality of substrates W in the vertical posture. The in-tank carrier 147 stores the plurality of substrates W spaced apart at a predetermined interval in a predetermined alignment direction. The in-tank carrier 147 has an opening provided at the bottom. The in-tank carrier 147 has an opening provided in the upper surface.

The immersion tank 143 accommodates the in-tank carrier 147. The immersion tank 143 includes ejection pipes 143a at both ends in the front-rear direction X on the bottom surface. Each of the ejection pipes 143a provides an upward flow of pure water directed upward from the bottom of the immersion tank 143. The pure water supplied to the immersion tank 143 from each of the ejection pipes 143a is discharged over an upper edge of the immersion tank 143.

The rotation mechanism 149 rotates the in-tank carrier 147 about the horizontal axis. The rotation mechanism 149 rotates the in-tank carrier 147 within the immersion tank 143.

The lifter LF4 includes a back plate portion 163 and a support portion 165. The back plate portion 163 extends along the inner surface of the immersion tank 143. To a lower end of the back plate portion 163, two support portions 165 are attached, for example. The lifter LF4 supports the in-tank carrier 147 such that a longitudinal direction of the carrier is in a horizontal posture.

A raising and lowering mechanism 167 is disposed near the lifter LF4. The raising and lowering mechanism 167 includes a motor 169, a ball screw 171, a linear guide 173, and raising and lowering pieces 175. A ball screw 171 is attached to a rotation shaft of the motor 169. The linear guide 173 is provided in parallel with the ball screw 171. The raising and lowering pieces 175 are screwed with the ball screw 171. One of the raising and lowering pieces 175 is slidably attached to the linear guide 173. The other of the raising and lowering pieces 175 is attached to the coupling member 177. The coupling member 177 has an inverted L shape. The coupling member 177 is coupled to an upper end of the back plate portion 163.

When the motor 169 is rotated, the lifter LF4 is moved up and down to a plurality of height positions.

For example, the lifter LF4 is moved up and down among a first height position P1, a second height position P2, a third height position P3, and a fourth height position P4 by the raising and lowering mechanism 167.

At the first height position P1, the support portion 165 of the lifter LF4 is located near the bottom surface of the immersion tank 143. The first height position P1 is a position where the in-tank carrier 147 is grasped by the rotation mechanism 149 and the support portion 165 is separated from a lower surface of the in-tank carrier 147. The first height position P1 is a position where the in-tank carrier 147 is longitudinally rotated in the immersion tank 143 by the rotation mechanism 149.

The second height position P2 is a position where the entire in-tank carrier 147 is supported below the liquid level of the immersion tank 143. At the second height position P2, the opening of the upper surface of the in-tank carrier 147 is located below the liquid level. The second height position P2 is a position where the grasping operation with respect to the in-tank carrier 147 is performed by the rotation mechanism 149.

The third height position P3 is a position where the plurality of substrates W are transferred between the second transport mechanism WTR and the in-tank carrier 147. For example, the support portion 165 of the lifter LF4 is positioned above the liquid level of the immersion tank 143 at the third height position P3.

The fourth height position P4 maintains the in-tank carrier 147 having the plurality of substrates W in the horizontal posture under the water surface in the immersion tank 143. The stepwise positions from the fourth height position P4 to the third height position P3 are the height positions at which only a substrate W that is an object to be transported by the center robot CR is positioned above the liquid level of the immersion tank 143.

In the immersion tank 143, a through hole 179 is formed at the bottom. The pusher 145 is attached to the through hole 179 so as to be movable up and down. The pusher 145 can collectively support the plurality of substrates W. The pusher 145 can move up and down through the in-tank carrier 147 in the vertical direction Z.

### <7. Details of Hand>

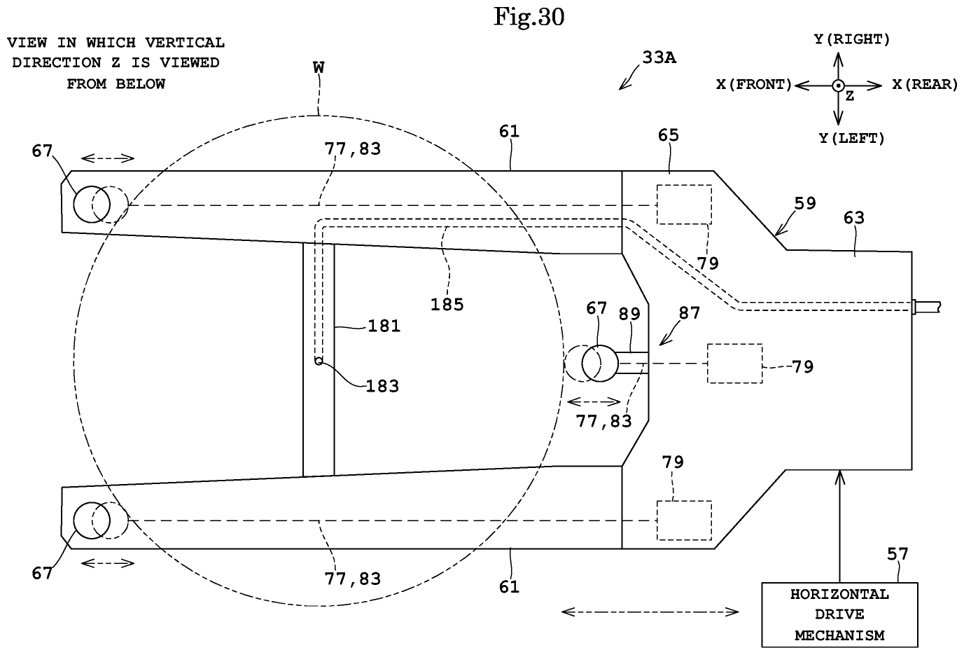

Out of the first hand 33A and the second hand 35A of the center robot CR, the first hand 33A will be described as an example with reference to FIG. 30. FIG. 30 is a plan view of the hand of the substrate processing device according to the fourth embodiment as viewed from below. The second hand 35A has the same configuration as the first hand 33A described below.

The first hand 33A has the same configuration as the first hand 19 according to the first embodiment. Here, the same components as those of the first hand 19 are denoted by the same reference numerals, and a detailed description thereof will be omitted. However, the first hand 33A is, for example, an upper pickup hand. Therefore, unlike the first hand 19, the first hand 33A includes the guides 67 on the lower surface.

The first hand 33A includes a beam portion 181 between the two finger portions 61. The beam portion 181 is preferably provided at a central portion in the front-rear direction X of the substrate W to be held. The beam portion 181 includes a nozzle 183. The nozzle 183 is preferably provided at the center in the width direction Y. The beam portion 181 is provided with the nozzle 183. The nozzle 183 is an opening. A side of one end of a flow path 185 is communicably connected to the nozzle 183. The flow path 185 is provided to penetrate the beam portion 181, one of the finger portions 61, and the palm portion 59. A side of the other end of the flow path 185 is communicably connected to a treatment liquid supply source (not illustrated).

The nozzle 183 discharges a treatment liquid. The nozzle 183 supplies the treatment liquid to the upper surface of the substrate W. The treatment liquid is, for example, pure water. The nozzle 183 moves together with the first hand 33A.

### <8. Description of Operation>

### <8-1. Batch Processing>

It is assumed that the plurality of substrates W are subjected to the etching treatment with phosphoric acid in the first batch processing unit BPU1, and then subjected to the pure water cleaning treatment in the third batch processing unit BPU3. The plurality of substrates W subjected to the pure water cleaning treatment are transported to the underwater posture converting unit 125 by the second transport mechanism WTR.

### <8-2. Posture Conversion>

The second transport mechanism WTR holds the plurality of substrates W processed by the third batch processing unit BPU3 with the hands 123 and transports the substrates W above the underwater posture converting unit 125. At this time, in the underwater posture converting unit 125, the support portion 165 of the lifter LF4 is located at the second height position P2. The in-tank carrier 147 is held by the support portion 165. Pure water overflows from an upper edge of the immersion tank 143. As a result, the immersion tank 143 is always filled with normal pure water. The rotation mechanism 149 is separated from the in-tank carrier 147. The pusher 145 is raised from a standby position to a transfer position of the immersion tank 143. As a result, lower edges of the plurality of substrates W held by the second transport mechanism WTR are abutted and supported by the pusher 145.

The second transport mechanism WTR releases the grasping of the hands 123 and opens the plurality of substrates W. As a result, the plurality of substrates W are transferred from the second transport mechanism WTR to the pusher 145. Next, the second transport mechanism WTR retracts from a position above the underwater posture converting unit 125.

The raising and lowering mechanism 167 drives the motor 169 to lift the lifter LF4 to the transfer position. Specifically, the lifter LF4 is raised to the third height position P3. As a result, the plurality of substrates W whose lower edges are supported by the pusher 145 are stored in the in-tank carrier 147.

The pusher 145 is lowered to the standby position. As a result, the plurality of substrates W are completely accommodated in the in-tank carrier 147.

The raising and lowering mechanism 167 rotatably drives the motor 169 to lower the lifter LF4 to the second height position P2.

The rotation mechanism 149 grasps the in-tank carrier 147. The in-tank carrier 147 is grasped in a state where its lower part is supported by the lifter LF4. Next, the motor 169 of the raising and lowering mechanism 167 is rotationally driven to lower the lifter LF4 to the first height position P1. As a result, the in-tank carrier 147 is grasped only by the rotation mechanism 149.

The rotation mechanism 149 of the posture converting unit 141 is operated. Specifically, the rotation mechanism 149 is rotationally driven to rotate the in-tank carrier 147 about an axis in the front-rear direction X. The rotation angle is 90°. As a result, the in-tank carrier 147 changes from the horizontal posture (horizontally long state) to the vertical posture (vertically long state). Therefore, the postures of the plurality of substrates W are converted from the vertical posture to the horizontal posture. At this time, the plurality of substrates W remains immersed in the pure water in the immersion tank 143. Even a part of the plurality of substrates W is not exposed from pure water when the posture conversion is performed.

The lifter LF4 is lifted to the fourth position P4 by the raising and lowering mechanism 167. As a result, the support portion 165 of the lifter LF4 holds the in-tank carrier 147 in the vertical posture in the liquid. Further, the rotation mechanism 149 is deactivated. The in-tank carrier 147 is held only by the lifter LF4.

The lifter LF4 is lifted from the fourth position P4 by the raising and lowering mechanism 167 to a position where only one of the substrates W at an uppermost position in the in-tank carrier 147 is exposed from the liquid level. The substrate W at the uppermost position is an object to be transported by the center robot CR. As a result, the substrate W at the uppermost position is exposed above the liquid surface of the immersion tank 143 in a state where the pure water stored in the immersion tank 143 is filled on the upper surface. In this state, the center robot CR advances the first hand 33A to the in-tank carrier 147 and takes out the substrate W at the uppermost position.

When the center robot CR moves to the underwater posture converting unit 125 to transport next one of the substrates W, the lifter LF4 is further lifted by the raising and lowering mechanism 167. As a result, only the next one of the substrates W is exposed above the liquid surface of the immersion tank 143. In this state, the center robot CR takes out the substrate W. As described above, every time the center robot CR moves, the lifter LF4 is gradually lifted by the raising and lowering mechanism 167. As a result, all the substrates W are transported by the center robot CR in a state in which the substrates are wet with pure water.

As described above, the substrates W not to be transported, which are not transported by the center robot CR, are located under the liquid level of the immersion tank 143. Therefore, it is possible to prevent the substrate W from being dried before the substrate W becomes an object to be transported by the center robot CR. As a result, collapse of the pattern on the substrate W can be suppressed.

### <8-3. Single Wafer Processing>

The substrate W transported by the center robot CR as described above is processed as follows, for example.

The center robot CR transports the substrate W to the first single wafer processing unit SWP1. At this time, pure water is preferably supplied from the nozzle 183 to the upper surface of the substrate W. As a result, when the substrate W is transported, it is possible to suppress the pure water from spilling from the upper surface and collapse of the pattern of the substrate W.

For example, the first single wafer processing unit SWP1 supplies pure water from the nozzle 135 while rotating the substrate W by the rotation processing unit 133. Thereafter, IPA is supplied from the nozzle 135 to the substrate W to replace pure water of the substrate W with IPA. Thereafter, the substrate W is carried out by the center robot CR and transported to the third single wafer processing unit SWP3. In the third single wafer processing unit SWP3, the substrate W is carried into the supercritical fluid chamber 137. The substrate W is dried with carbon dioxide in the supercritical fluid chamber 137. A finish drying treatment is performed on the substrate W by the drying treatment in the supercritical fluid chamber 137. As a result, the substrate W is completely dried, but collapse of the pattern provided on the substrate W is suppressed.

The substrate W processed in the supercritical fluid chamber 137 is transported to the buffer unit 131 by the center robot CR. The center robot CR places the substrate W on the placement shelf 139 of the buffer unit 131. When the substrates W for one lot are placed on the buffer unit 131, the first transport mechanism HTR transports the plurality of substrates W to the transport storage unit ACB at one time. The transport storage unit ACB transports the substrates W with the carrier C in whole to the unload unit 113. The single wafer processing and the subsequent transportation as described above are performed on all the substrates W in the in-tank carrier 147. Thus, the batch processing and the single wafer processing can be performed on all of the plurality of substrates W.

According to the fourth embodiment, the plurality of substrates W processed by the third batch processing unit BPU3 are transported to the posture converting unit 141 by the second transport mechanism WTR. At this time, the plurality of substrates W are immersed in pure water in the immersion tank 143 until the posture conversion is performed. Therefore, when the posture conversion is performed to the plurality of substrates W in the vertical posture to the horizontal posture, the entire substrate W can be always wet. As a result, even when the substrate W is transported for the single wafer processing by the center robot CR, collapse of the pattern on the substrate W can be suppressed.

Furthermore, the first hand 33A of the center robot CR includes the nozzle 183. Therefore, even if pure water spills down from the substrate W during transportation, pure water can be supplied from the nozzle 183. Accordingly, it is not necessary to transport the substrate W at a low speed so that pure water does not spill from the substrate W. As a result, in addition to the effect of the first embodiment described above, it is possible to suppress a decrease in throughput even when the substrate W is transported in a wet state.

In addition, since the nozzle 183 is provided in the beam portion 181 suspended between the two finger portions 61, the treatment liquid can be supplied to the central portion of the substrate W. Thus, the treatment liquid can be uniformly supplied over the entire surface of the substrate W.

The correspondence between the fourth embodiment described above and the configuration of the present invention is as follows.

The center robot CR corresponds to a “substrate transport apparatus” in the present invention. The two finger portions 61 correspond to “two extending portions” in the present invention. The first batch processing unit BPU1, the second batch processing unit BPU2, the third batch processing unit BPU3, the underwater posture converting unit 125, the first single wafer processing unit SWP1, the second single wafer processing unit SWP2, and the third single wafer processing unit SWP3 correspond to “processors” in the present invention.

The present invention is not limited to the above embodiment, and can be modified as follows.

(1) In each of the first to fourth embodiments described above, the configurations of the substrate processing devices 1 and 1A have been described as examples, but the present invention is not limited to the substrate processing device having such a configuration.

(2) In the first to fourth embodiments described above, the case in which the substrate W in a circular shape has been described as an example, but the substrate W is not limited to a circular shape.

(3) In each of the first to fourth embodiments described above, the configuration in which only one of the upper pickup hand and the lower pickup hand is adopted has been shown. However, for example, the center robot CR of the substrate processing device 1 includes the first hand 33 and the second hand 35, but hands of different pickup types may be adopted.

For example, in the center robot CR, the first hand 33 is an upper pickup hand, and the second hand 35 is a lower pickup hand. Furthermore, the first hand 33 and the second hand 35 may be selectively used according to the clearance CL1 of the placement unit 47A and the clearance CL2 of the placement unit 47B included in the processing unit 31.

Therefore, the substrate W can be reliably transported by selecting an appropriate hand (the first hand 33 or the second hand 35) according to the clearance CL1 or CL2 related to the transfer of the substrate W in the processing unit 31.

What is claimed is:

1. A substrate transport apparatus that transports a substrate, the apparatus comprising:
a hand configured to hold the substrate in a horizontal posture;
a horizontal drive mechanism configured to drive the hand to advance and retreat in a horizontal plane in order to transfer the substrate;
at least two guides disposed on the hand, and configured to hold the substrate away from the hand by grasping an outer peripheral surface of the substrate;
an advance and retreat drive mechanism configured to drive at least one of the at least two guides as a movable guide to advance and retreat with respect to the substrate; and
a control unit configured to control the advance and retreat drive mechanism to adjust a biasing force by the movable guide to the outer peripheral surface of the substrate.

2. The substrate transport apparatus according to claim 1, wherein
the control unit adjusts the biasing force of the movable guide to the outer peripheral surface of the substrate according to a shape of the substrate.

3. The substrate transport apparatus according to claim 2, wherein
the control unit adjusts the biasing force of the movable guide to the outer peripheral surface of the substrate such that the biasing force decreases as a thickness of the substrate decreases.

4. The substrate transport apparatus according to claim 2, wherein
the control unit adjusts the biasing force of the movable guide to the outer peripheral surface of the substrate such that the biasing force decreases as warpage of the substrate increases.

5. The substrate transport apparatus according to claim 1, further comprising:
an outer peripheral surface detection unit configured to detect that the movable guide abuts on the outer peripheral surface of the substrate, wherein
the control unit adjusts the biasing force after the outer peripheral surface detection unit detects that the movable guide abuts on the outer peripheral surface of the substrate.

6. The substrate transport apparatus according to claim 1, wherein
all of the guides are movable guides, and
when the substrate is held by the hand, the control unit moves all of the movable guides to the outer peripheral surface of the substrate by operating respective advance and retreat drive mechanisms, and adjusts biasing forces for the all of the movable guides by the respective advance and retreat drive mechanisms.

7. The substrate transport apparatus according to claim 5, wherein
the outer peripheral surface detection unit is a tactile sensor including a detection surface capable of detecting a force applied to each of three orthogonal axes.

8. The substrate transport apparatus according to claim 5, wherein
the advance and retreat drive mechanism includes a motor, a drive circuit, and an encoder, the motor driving the guide to advance and retract, the drive circuit applying a drive current for driving the motor, the encoder detecting a rotational position of the motor,
the outer peripheral surface detection unit includes at least one of a drive current detection unit and a position information detection unit, the drive current detection unit detecting the abutment based on drive current information of the drive circuit, the position information detection unit detecting the abutment based on position information output from the encoder, and
the control unit determines the abutment based on at least one of the drive current information and the position information.

9. The substrate transport apparatus according to claim 5, wherein
the outer peripheral surface detection unit is provided for the movable guide at an attachment portion to the hand.

10. The substrate transport apparatus according to claim 1, wherein
the guide is attached to a lower surface of the hand.

11. The substrate transport apparatus according to claim 1, wherein
the guide has a columnar shape.

12. The substrate transport apparatus according to claim 1, wherein
the guide includes an inclined surface and a grasping portion, the inclined surface being lowered toward a center side of the substrate, the grasping portion being erected along the outer peripheral surface of the substrate,
when receiving the substrate, the hand grasps the substrate by pressing the substrate against the grasping portion by the movable guide applying a biasing force to the outer peripheral surface of the substrate after the substrate is once placed on the inclined surface, and
the guide includes a placement detection unit configured to detect that the substrate is placed on the inclined surface.

13. The substrate transport apparatus according to claim 1, wherein
the hand further includes a nozzle configured to supply a treatment liquid to an upper surface of the substrate grasped by the guide.

14. The substrate transport apparatus according to claim 13, wherein
the hand includes two extending portions and a beam portion, the extending portions extending from a proximal end to a distal end, the beam portion being suspended between the two extending portions so as to pass through a center portion of the substrate grasped by the hand, and
the nozzle is provided for the beam portion and supplies the treatment liquid to the substrate grasped by the hand.

15. The substrate transport apparatus according to claim 1, wherein
the hand includes two types of pickup hands including an upper pickup hand having the guide on a lower surface thereof and a lower pickup hand having the guide on an upper surface thereof, and
according to a clearance as a distance between an upper surface of a placement unit as a transfer destination and a lower surface of the substrate, the substrate is transferred to and from the placement unit by using the lower pickup hand for the placement unit having a large clearance, and using the upper pickup hand for the placement unit having a small clearance.

16. A substrate processing device comprising:
the substrate transport apparatus according to claim 1; and
a processor configured to perform predetermined processing on the substrate.
